(19) United States
(12) Patent Application Publication
(10) Pub. No.: US 2026/0123248 A1
(43) Pub. Date: Apr. 30, 2026

(54) DISPLAY PANEL AND LIGHT EMITTING DISPLAY APPARATUS

(71) Applicant: LG DISPLAY CO., LTD., Seoul (KR)

(72) Inventors: Inae CHOI, Paju-si (KR); Sejong SEONG, Paju-si (KR); Taehyeon KIM, Paju-si (KR)

(73) Assignee: LG DISPLAY CO., LTD., Seoul (KR)

(21) Appl. No.: 19/003,924

(22) Filed: Dec. 27, 2024

(30) Foreign Application Priority Data
Dec. 28, 2023 (KR) 10-2023-0194555

(51) Int. Cl. H10K 59/80; H10K 59/121; H10K 59/122; H10K 59/131

(52) U.S. Cl. CPC H10K 59/879; H10K 59/1213; H10K 59/122; H10K 59/131

(57) ABSTRACT

Disclosed are a display panel and a light emitting display apparatus. In some embodiments, the display panel can include a subpixel disposed on a substrate, the subpixel having a pattern portion disposed on the substrate, a first emission portion disposed over a center of the pattern portion, a second emission portion disposed on a first inclined surface of the pattern portion, and a third emission portion disposed on a second inclined surface of the pattern portion.

### CROSS-REFERENCE TO RELATED APPLICATIONS

This application claims priority to Korean Patent Application No. 10-2023-0194555 filed in the Republic of Korea on Dec. 28, 2023, the entirety of which is hereby incorporated by reference into the present application as if fully set forth herein.

### BACKGROUND

### Technical Field

The present disclosure relates to display field, specifically, to a display panel and a light emitting display apparatus which displays an image.

### Discussion of the Related Art

A light emitting display apparatus exhibits a high response speed while maintaining low power consumption. For example, a light emitting display apparatus displays an image through light emission of a light emitting device including an emission layer interposed between two electrodes. Unlike a liquid crystal display apparatus, the light emitting display apparatus is a self-emissive display device and does not require a separate light source (e.g., no backlight unit). Thus, there is typically no problem with the viewing angle. Accordingly, a light emitting display apparatus has received attention as a next generation flat panel display apparatus.

However, since some of the light emitted from the light emitting device is not emitted to the outside due to total reflection at the interface between the light emitting device and the electrode and/or total reflection at the interface between the substrate and the air layer, the light extraction efficiency is reduced. Accordingly, the light emitting display apparatus has problems in that brightness is reduced due to low light extraction efficiency, and power consumption is increased.

Also, there is an issue with the light emitting device that the subpixels often have a large footprint in order to provide a certain level of brightness, which can lead to constraints for higher resolution devices.

Thus, there exists a need for a subpixel configuration that can allow for more light to be output in a direction toward a user while using a smaller footprint, which can provide smaller and brighter subpixels that can save space, provide a wider viewing angle, increase resolution and reduce power consumption.

Also, there exists a need for a subpixel configuration that can provide different viewing modes (e.g., two-dimensional (2D) mode, three-dimensional (3D) mode, wide angle viewing mode, narrow angle viewing mode, low brightness mode, high brightness mode).

### SUMMARY OF THE DISCLOSURE

Accordingly, an aspect of the present disclosure is directed to providing a light emitting display apparatus that substantially obviates one or more problems due to limitations and disadvantages of the related art.

An aspect of the present disclosure is to provide a light emitting display apparatus that can enhance light extraction efficiency of light which is emitted from a light emitting device.

An aspect of the present disclosure is directed to providing a light emitting display apparatus in which light extraction efficiency can increase and a viewing angle can increase.

Another aspect of the present disclosure is directed to providing a light emitting display apparatus which can implement a stereoscopic image (e.g., 3D image).

The aspects of the present disclosure are not limited to the aforesaid, but other aspects not described herein will be clearly understood by those skilled in the art from the description herein.

To achieve these and other aspects of the present disclosure, as embodied and broadly described herein, in one or more aspects, a light emitting display apparatus comprises a substrate, and a plurality of pixels including a plurality of subpixels on the substrate. Each of the plurality of subpixels comprises a first emission portion, a second emission portion at a first side of the first emission portion, and a third emission portion at a second side different from the first side of the first emission portion. Each of the second emission portion and the third emission portion is inclined from the first emission portion.

According to one or more embodiments of the present disclosure, the second emission portion and the third emission portion are parallel to each other with the first emission portion therebetween, and an angle of light emitted from each of the second emission portion and the third emission portion differs from an angle of light emitted from the first emission portion.

According to one or more embodiments of the present disclosure, each of the plurality of subpixels comprises a pixel circuit connected to the first to third emission portions, a protection layer covering the pixel circuit, a pattern portion over the protection layer, and a light emitting device over the pattern portion. The first to third emission portions are configured at the pattern portion.

A light emitting display apparatus according to one or more embodiments of the present disclosure comprises a substrate, and a plurality of pixels including a plurality of subpixels on the substrate. Each of the plurality of subpixels comprises a flat emission portion, a first slope emission portion at a first side of the flat emission portion, and a second slope emission portion at a second side different from the first side of the flat emission portion. According to one or more embodiments of the present disclosure, each of the first slope emission portion and the second slope emission portion is inclined with respect to the substrate.

According to one or more embodiments of the present disclosure, each of the plurality of subpixels comprises a pixel circuit connected to the flat emission portion, the first slope emission portion, and the second slope emission portion; a protection layer covering the pixel circuit; a pattern portion over the protection layer; and a light emitting device over the pattern portion. The flat emission portion, the first slope emission portion, and the second slope emission portion are configured at the pattern portion.

In one or more aspects, a display panel comprises a subpixel disposed on a substrate, the subpixel including: a pattern portion disposed on the substrate; a first emission portion disposed over a center of the pattern portion; a second emission portion disposed on a first inclined surface of the pattern portion; and a third emission portion disposed on a second inclined surface of the pattern portion.

In the light emitting display apparatus and/or display panel according to one or more embodiments of the present disclosure, the light extraction efficiency of light which is emitted from a light emitting device can be improved.

In the light emitting display apparatus and/or display panel according to one or more embodiments of the present disclosure, light extraction efficiency can increase and a viewing angle can increase.

The light emitting display apparatus and/or display panel according to one or more embodiments of the present disclosure can display a stereoscopic image, and thus, can implement (or display) a stereoscopic image display apparatus. For example, the light emitting display apparatus or the stereoscopic image display apparatus according to one or more embodiments of the present disclosure can implement (or display) a stereoscopic image based on a light field mode (or a light field type).

Other aspects, features and advantages of the present disclosure are set forth in the present disclosure and will also be apparent from the present disclosure or can be learned by practice of the inventive concepts provided herein. Other aspects, features and advantages of the present disclosure can be realized and attained by the descriptions provided in the present disclosure, including the claims and the drawings.

Furthermore, other devices, methods, features and advantages will be, or will become, apparent to one with skill in the art upon examination of the drawings and detailed description herein. It is intended that all such devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples and explanatory, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles of the disclosure.

FIG. 1 is a view schematically illustrating a light emitting display apparatus according to an example embodiment of the present disclosure.

FIG. 2 is a plan view illustrating one pixel illustrated in FIG. 1 according to an embodiment of the present disclosure.

FIG. 3 is an equivalent circuit view illustrating a first subpixel illustrated in FIG. 2 according to an embodiment of the present disclosure.

FIG. 4 is a cross-sectional view taken along line I-I′ illustrated in FIG. 2 according to an embodiment of the present disclosure.

FIG. 5 is a cross-sectional view taken along line II-II′ illustrated in FIG. 2 according to an embodiment of the present disclosure.

FIG. 6 is an enlarged view of part “A” illustrated in FIG. 5 according to an embodiment of the present disclosure.

FIG. 7 is another plan view illustrating one pixel illustrated in FIG. 1 according to an embodiment of the present disclosure.

FIG. 8 is an equivalent circuit view illustrating a first subpixel illustrated in FIG. 7 according to an embodiment of the present disclosure.

FIG. 9 is a cross-sectional view taken along line III-III′ illustrated in FIG. 7 according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof can be exaggerated for clarity, illustration, and convenience.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a situation where “comprise,” “have,” and “include” described in the present specification are used, another part can be added unless “only” is used. The terms of a singular form can include plural forms unless referred to the contrary.

In construing an element, the element is construed as including an error range although there is no explicit description.

In describing a position relationship, for example, when a position relation between two parts is described as “on,” “over,” “under,” and “next,” one or more other parts can be disposed between the two parts unless ‘just’ or ‘direct’ is used.

In describing a temporal relationship, for example, when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” or the like can be used. These terms are intended to identify the corresponding element(s) from the other element(s), and these are not used to define the essence, basis, order, or number of the elements. For the expression that an element is “connected,” “coupled,” or “contact,” to another element, the element may not only be directly connected, coupled, or contacted to another element, but also be indirectly connected, coupled, or contacted to another element with one or more intervening elements interposed between the elements, unless otherwise specified.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

“X-axis direction,” “Y-axis direction” and “Z-axis direction” should not be construed by a geometric relation only of a mutual vertical relation and can have broader directionality within the range that elements of the present disclosure can act functionally.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, example embodiments of a light emitting display apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

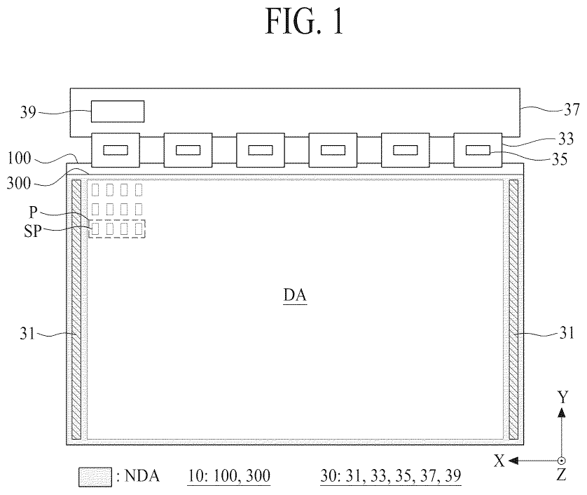

FIG. 1 is a view schematically illustrating a light emitting display apparatus according to an example embodiment of the present disclosure.

Referring to FIG. 1, a light emitting display apparatus according to an embodiment of the present disclosure can be a flexible light emitting display apparatus, an organic light emitting display apparatus, a flexible organic light emitting display apparatus, or a light field display apparatus, and the like, but embodiments of the present disclosure are not limited thereto. For example, the light emitting display apparatus according to an embodiment of the present disclosure can include a set electronic apparatus or a set device (or a set apparatus) such as a notebook computer, a television, a computer monitor, an equipment apparatus including an automotive apparatus or another type apparatus for vehicles, or a mobile electronic apparatus such as a smartphone or an electronic pad, which is a complete product (or a final product) including a display panel.

A light emitting display apparatus or a light emitting display panel according to one or more embodiments of the present disclosure can be applied to or included in any electronic apparatuses. The light emitting display apparatus or the light emitting display panel according to one or more embodiments of the present disclosure can be applied to or included in mobile apparatuses, video phones, smart watches, watch phones, wearable apparatuses, foldable apparatuses, rollable apparatuses, bendable apparatuses, flexible apparatuses, curved apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, TVs, game machines, notebook computers, monitors, cameras, camcorders, and home appliances, or the like. In addition, the light emitting display apparatus or the light emitting display panel according to one or more embodiments of the present disclosure can be applied to or included in wallpaper display apparatuses, signage apparatuses, a window-type displays, a smart show windows, a smart mirrors, or a bidirectional information transfer apparatuses, or a stereoscopic image display apparatuses, or the like, but embodiments of the present disclosure are not limited thereto.

The light emitting display apparatus according to an embodiment of the present disclosure can include a display panel 10.

The display panel 10 can include a substrate 100. The substrate 100 includes a thin film transistor, and the substrate 100 can be a first substrate, a base substrate, a lower substrate, a transparent glass substrate, a transparent plastic substrate, or a base member.

The display panel 10 or the substrate 100 can include a display area (or a display portion) DA and a non-display area (or a non-display portion). The display area DA is an area in which an image is displayed, and can be disposed at a central area of the display panel 10. The non-display area is an area in which an image is not displayed, and can be configured to surround the display area DA (e.g., a bezel area).

The display panel 10 includes a plurality of pixels P provided (or configured) on the substrate 100. The display panel 10 or the substrate 100 includes a plurality of pixels P provided (or configured) at the display area DA. Each of the plurality of pixels P can include a plurality of subpixels SP. Each of the plurality of pixels P can be disposed (or arranged) along a first direction (X) and a second direction Y which intersects with the first direction X. For example, in the present disclosure, the first direction X can be an X-axis direction or a horizontal direction of the display panel 10 or the substrate 100. The second direction Y can be a Y-axis direction or a vertical direction of the display panel 10 or the substrate 100.

Each of the plurality of subpixels SP can be defined as a point light source emitting light. At least three subpixels SP disposed to be adjacent to each other among the plurality of subpixels SP can configure a pixel (or a unit pixel) P. According to an embodiment, at least four subpixels, which are provided to emit different colors and disposed to be adjacent to one another among the plurality of subpixels SP can configure one pixel P. One pixel P can include a red subpixel (or a first subpixel), a blue subpixel (or a second subpixel), a white subpixel (or a third subpixel), and a green subpixel (or a fourth subpixel), but is not limited thereto. According to another embodiment, one pixel P can include three subpixels SP, which are provided to emit different colors and disposed to be adjacent to one another among the plurality of subpixels SP. For example, one pixel P can include a red subpixel (or a first subpixel), a blue subpixel (or a second subpixel), and a green subpixel (or a third subpixel).

Each of the plurality of subpixels SP according to an embodiment of the present disclosure can include a plurality of emission portions (or emission areas). For example, each of the plurality of subpixels SP can include a main emission portion and a plurality of sub emission portions. For example, each of the plurality of subpixels SP can include a main emission portion and a plurality of sub emission portions which are disposed adjacent to the main emission portion and are inclined with respect to the substrate 100. For example, each of the plurality of subpixels SP can include a first emission portion (or the main emission portion), a second emission portion (or a first sub emission portion) which is at a first side of the first emission portion, and a third emission portion (or a second sub emission portion) which is at a second side, which is different from or opposite to the first side, of the first emission portion.

According to an embodiment of the present disclosure, the first emission portion can be disposed at a first region (or a middle region) of each of the plurality of subpixels SP. The second emission portion can be disposed at a second region (or one region or one edge region of the first region) of each of the plurality of subpixels SP. The third emission portion can be disposed at a third region (or the other region or the other edge region of the first region) of each of the plurality of subpixels SP. For example, the second emission portion and the third emission portion can be disposed (or configured) in parallel with the first emission portion therebetween.

According to an embodiment of the present disclosure, an angle of light emitted from each of the second emission portion and the third emission portion can differ from an angle of light emitted from the first emission portion. For example, a light extraction surface (or a light output surface) of the first emission portion can be parallel to the substrate 100, and a light extraction surface (or a light output surface) of each of the second emission portion and the third emission portion can be inclined or sloped with respect to the substrate 100. For example, the first emission portion can be configured to output light in a direction perpendicular to a surface of the substrate 100, and the second emission portion and the third emission portion can be configured to output light in a direction which is inclined (e.g., a diagonal direction) with respect to the surface of the substrate 100.

According to an embodiment of the present disclosure, each of the second emission portion and the third emission portion can be inclined or sloped with respect to the first emission portion. Each of the second emission portion and the third emission portion can be configured to be inclined with respect to the substrate 100. For example, the first emission portion can include a flat structure which is disposed (or configured) on a flat surface, and the second emission portion and the third emission portion can include a slope structure or a tilt structure, which is disposed (or configured) on a slope surface that is inclined with respect to the flat surface. For example, the second emission portion and the third emission portion can include a slope structure or a tilt structure, which is disposed (or configured) on the slope surface inclined with respect to the substrate 100.

The light emitting display apparatus according to an embodiment of the present disclosure can display an image through the main emission portion and the plurality of sub emission portions each configured at each of the plurality of subpixels SP, and a viewing angle can be increased or widened by the plurality of sub emission portions. Also, one or more of the plurality of sub emission portions can be turned off or on in order to adjust or narrow the viewing angle (e.g., to provide a privacy mode, or a low brightness mode, etc.). In addition, the light emitting display apparatus according to an embodiment of the present disclosure can display a stereoscopic image through the individual light emission of each of the main emission portion and the plurality of sub emission portions each configured in each of the plurality of subpixels SP, and thus, can implement (or display) a stereoscopic image (e.g., a 3D mode, a stereoscopic image of a light field mode or a light field type) or can provide a stereoscopic image to a user (or a viewer).

The display panel 10 can further include a counter substrate (or opposite substrate) 300. The counter substrate 300 can be configured to encapsulate (or seal) the display area DA disposed over the substrate 100. For example, the counter substrate 300 can be opposite-bonded to the substrate 100 using an adhesive member (or transparent adhesive). The counter substrate 300 can be an upper substrate, a second substrate, or an encapsulation substrate.

The light emitting display apparatus according to an embodiment of the present disclosure can further include a driving circuit part 30.

The driving circuit part 30 can be configured to display an image corresponding to image data supplied from a display driving system (or a host system) in each pixel P.

The driving circuit part 30 according to an embodiment of the present disclosure can include a gate driving circuit 31, a plurality of flexible circuit films 33, a plurality of driving integrated circuits (ICs) 35, a printed circuit board (PCB) 37, and a control circuit part 39 (e.g., controller, or timing controller).

The gate driving circuit 31 can be disposed (or configured) at a non-display area DA of the substrate 100 and can be connected to the plurality of subpixels SP. The gate driving circuit 31 according to an embodiment of the present disclosure can be integrated with one non-display area or both non-display area of the substrate 100 in accordance with a manufacturing process of a thin film transistor, and can be connected to the plurality of subpixels SP. For example, the gate driving circuit 31 can include a generally known shift register.

Each of the plurality of flexible circuit films 33 can be configured to be electrically connected between the PCB 37 and a pad part provided at one edge portion of the substrate 100. Each of the plurality of flexible circuit film 33 according to an embodiment of the present disclosure can be a tape carrier package (TCP) or a chip-on film (COF), but is not limited thereto.

Each of the plurality of driving ICs 35 can be individually mounted on (or at) a corresponding flexible circuit film 33 of the plurality of flexible circuit films 33. Each of the plurality of driving ICs 35 can receive subpixel data and a data control signal provided from the control circuit part 39, convert the subpixel data into a subpixel-based analog data voltage according to the data control signal, and supply the analog data voltage to a corresponding subpixel SP. For example, each of the plurality of driving ICs 35 can generate a plurality of grayscale voltages by using a plurality of reference gamma voltages provided from the PCB 37 and can select, as a subpixel-based data voltage, a grayscale voltage corresponding to the subpixel data from among the plurality of grayscale voltages to output the selected data voltage.

Each of the plurality of driving ICs 35 can sequentially sense a characteristic value of a driving transistor configured at the subpixel SP through the plurality of reference voltage lines disposed (or configured) on the substrate 100 to be connected to each of the plurality of subpixels SP, generate sensing raw data corresponding to a sensing value, and provide the sensing raw data to the control circuit part 39.

The PCB 37 can be electrically connected to each of the plurality of flexible circuit films 33. The PCB 37 can serve to transmit a signal and a voltage between elements of the driving circuit part 39.

The control circuit part 39 can be mounted on the PCB 37 and can receive image data and a timing synchronization signal provided from the display driving system through a user connector disposed at the PCB 37. Alternatively, the control circuit part 39 may not be mounted on the PCB 37 and can be configured in the display driving system or can be mounted on a separate control board connected between the PCB 37 and the display driving system.

The control circuit part 39 can generate each of the data control signal and a gate control signal based on the timing synchronization signal, control a driving timing of each of the driving ICs 35 based on the data control signal, and control a driving timing of the gate driving circuit 31 based on the gate control signal. For example, the timing synchronization signal can include a vertical synchronization signal, a horizontal synchronization signal, a data enable signal, and a main clock (or a dot clock).

The control circuit part 39 can align the image data based on the timing synchronization signal to match a pixel arrangement structure disposed at the display area DA and can be configured to provide the generated pixel data to each of the plurality of driving ICs 35.

According to an embodiment of the present disclosure, when the pixel P includes a white subpixel emitting white light, the control circuit part 39 can extract white pixel data based on the digital image data (e.g., red input data, green input data, and blue input data which are to be respectively supplied to corresponding pixels P), reflect offset data based on the extracted white pixel data in each of the red input data, the green input data, and the blue input data to calculate red pixel data, green pixel data, and blue pixel data, and align the calculated red pixel data, green pixel data, and blue pixel data and the white pixel data according to the pixel arrangement structure to supply aligned pixel data to each of the driving ICs 35.

According to an embodiment of the present disclosure, the control circuit part 39 can generate subpixel-based subpixel data corresponding to each of the plurality of subpixels SP to supply to each of the plurality of driving ICs 35, based on red input data, green input data, and blue input data which are to be respectively supplied to the plurality of subpixels SP. Each of the plurality of driving ICs 35 can convert the subpixel-based subpixel data, provided from the control circuit part 39, into a subpixel-based data voltage to supply to a corresponding subpixel SP.

According to another embodiment of the present disclosure, the control circuit part 39 can generate main data and a plurality of sub data corresponding to each of the plurality of subpixels SP to supply to each of the plurality of driving ICs 35, based on red input data, green input data, and blue input data which are to be respectively supplied to the plurality of subpixels SP. For example, the control circuit part 39 can generate first field data (or a main data), second field data (or a first sub data), and third field data (or a second sub data) respectively corresponding to the plurality of subpixels SP to supply to each of the plurality of driving ICs 35. Each of the plurality of driving ICs 35 can respectively convert subpixel-based first field data, second field data, and third field data provided from the control circuit part 39 into a first field data voltage (or a main field data voltage), a second field data voltage (or a first sub field data voltage), and a third field data voltage (or a second sub field data voltage) to supply to a corresponding subpixel SP.

According to another embodiment of the present disclosure, the control circuit part 39 can generate subpixel-based subpixel data corresponding to each of the plurality of subpixels SP to supply to each of the plurality of subpixels SP, based on a normal driving mode of the light emitting display apparatus. Also, the control circuit part 39 can generate main data and a plurality of sub data corresponding to each of the plurality of subpixels SP to supply to each of the plurality of driving ICs 35, based on a light field driving mode (or a stereoscopic image display mode) of the light emitting display apparatus. For example, the control circuit part 39 can generate first to third field data respectively corresponding to the plurality of subpixels SP to supply to each of the plurality of driving ICs 35, based on the light field driving mode of the light emitting display apparatus.

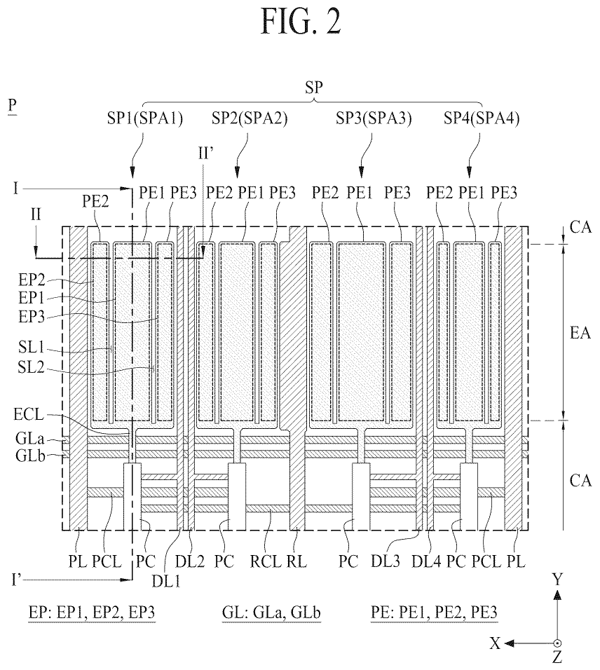

FIG. 2 is a plan view illustrating one pixel illustrated in FIG. 1, according to an embodiment of the present disclosure.

Referring to FIGS. 1 and 2, in a light emitting display apparatus (or light emitting display panel) according to an embodiment of the present disclosure, each of a plurality of pixels P can include a plurality of subpixels SP1, SP2, SP3 and SP4.

Each of the plurality of pixels P can include first, second, third and fourth subpixels SP1, SP2, SP3 and SP4 adjacent to one another along a first direction X. For example, each of the plurality of pixels P can include a red subpixel SP1, a blue subpixel SP2, a white subpixel SP3, and a green subpixel SP4, but embodiments according to the present disclosure are not limited thereto. For example, each of the plurality of pixels P can include a red subpixel SP1, a white subpixel SP2, a blue subpixel SP3, and a green subpixel SP4, but embodiments according to the present disclosure are not limited thereto. Each of the first to fourth subpixels SP1 to SP4 can be configured to have different sizes (or areas) and/or different shapes from each other. Also, the various emission portions of the subpixels are shown as having rectangular shapes in FIG. 2 as an example, but embodiments are not limited thereto. For example, the emission portions of the subpixels can have various shapes, such as triangular, oval, square, circular or various polygons having more than 4 sides, or shapes with rounded edges etc.

Each of the plurality of pixels P can be connected to a gate line GL, a driving voltage line PL, first to fourth data lines DL1 to DL4, and a reference voltage line RL.

The gate line GL can be disposed (or configured) in parallel to the first direction X. The gate line GL can be configured to be connected to the plurality of subpixels SP1 to SP4 disposed along the first direction X in common. For example, the gate line GL can include first and second gate lines GLa and GLb. The first and second gate lines GLa and GLb can extend lengthwise along the first direction X and can be disposed (or configured) to be spaced apart from each other along a second direction Y. For example, the first and second gate lines GLa and GLb can be configured to be connected to the plurality of subpixels SP1 to SP4 disposed along the first direction X in common. The gate line GL can be electrically connected to the gate driving circuit 31 and can be configured to supply a gate signal, supplied from the gate driving circuit 31, to the plurality of subpixels SP1 to SP4.

The driving voltage line PL can be disposed (or configured) in parallel to the second direction Y. The driving voltage line PL can be configured to be connected to the plurality of subpixels SP1 to SP4 in common. For example, the display panel 10 can include a plurality of driving voltage lines PL which extend lengthwise along the second direction Y and are spaced apart from one another along the first direction X. The plurality of pixels P can be disposed between the plurality of driving voltage lines PL.

The first to fourth data lines DL1 to DL4 can extend lengthwise along the second direction Y and can be disposed (or configured) to be spaced apart from each other along the first direction X. For example, the first to fourth data lines DL1 to DL4 can be configured to be electrically connected to different subpixels SP1 to SP4 in the pixel P. According to an embodiment, the first data line DL1 and the second data line DL2 can be disposed in parallel between the first subpixel SP1 and the second subpixel SP2. The third data line DL3 and the fourth data line DL4 can be disposed in parallel between the third subpixel SP3 and the fourth subpixel SP4. The first to fourth data lines DL1 to DL4 can be electrically connected to the plurality of driving ICs 35 and can be configured to supply a data signal, supplied from the plurality of driving ICs 35, to the plurality of subpixels SP1 to SP4.

The reference voltage line RL can be disposed (or configured) to extend lengthwise along the second direction Y. The reference voltage line RL can be configured to be connected to the plurality of subpixels SP1 to SP4 in common. According to an embodiment, the reference voltage line RL can be disposed between the second subpixel SP2 and the third subpixel SP3. The reference voltage line RL can be used as a sensing line for sensing a change of characteristics of a driving transistor and/or a change of characteristics of the light emitting device, which is disposed in the subpixels SP1 to SP4, from the outside in a sensing driving mode of the pixel P.

Each of the first to fourth subpixels SP1 to SP4 can be configured to display images in accordance with gate signals supplied from the gate lines GL adjacent thereto and data signals supplied from the data lines DL adjacent thereto.

Each of the first to fourth subpixels SP1 to SP4 can include an emission area EA and a circuit area CA. The circuit area CA may be located in a non-emission area NEA. The emission area EA can be disposed at one side (or an upper side) of a subpixel area SPA1 to SPA4. The emission area EA of each of the first to fourth subpixels SP1 to SP4 can have different sizes (or areas) from each other, but is not limited thereto. For example, the emission area EA can be an opening area (or an opening region) or a light emitting area (or a light emitting region). According to an embodiment, the emission area EA of the third subpixel SP3 can have the greatest size of the emission area EA of the first to fourth subpixel SP1 to SP4, the emission area EA of the fourth subpixel SP4 can have the smallest size of the emission area EA of the first to fourth subpixel SP1 to SP4, and the emission area EA of the first subpixel SP1 can have a size which is smaller than the emission area EA of the third subpixel SP3 and is greater than the emission area EA of each of the second and fourth subpixels SP2 and SP4. In addition, the emission area EA of the second subpixel SP2 can have a size which is greater than the emission area EA of the fourth subpixel SP4.

The circuit area CA of each of the first to fourth subpixels SP1 to SP4 can be spatially separated from the emission area EA within the subpixel area SPA1 to SPA4. For example, the circuit area CA can be disposed at the other side (or a lower side) of the subpixel area SPA1 to SPA4, but is not limited thereto. For example, at least a portion of the circuit area CA can overlap with the emission area EA within the subpixel area SPA1 to SPA4. For example, the circuit area CA can overlap an entire emission area EA within the subpixel area SPA1 to SPA4, or can be disposed under (or below) the emission area EA within the subpixel area SPA1 to SPA4. For example, the circuit area CA can be a non-emission area (or a non-emission region) or a non-opening area (or a non-opening region).

Each of the plurality of subpixels SP1 to SP4 according to an embodiment of the present disclosure can include an emission portion EP. Each of the first to fourth subpixels SP1 to SP4 according to an embodiment of the present disclosure can include an emission portion EP corresponding to the emission area EA of each of subpixel areas SPA1 to SPA4.

The emission portion of each of the first to fourth subpixels SP1 to SP4 can include a plurality of emission portions EP1, EP2, and EP3. At least some of the plurality of emission portions EP1, EP2, and EP3 can have different sizes and different shapes (or areas). One of the plurality of emission portions EP1, EP2, and EP3 can have a relatively large size (or area). Some of the plurality of emission portions EP1, EP2, and EP3 can be configured to be inclined with respect to the substrate 100. Some of the plurality of emission portions EP1, EP2, and EP3 can be configured to have different emission angles. Some of the plurality of emission portions EP1, EP2, and EP3 can be configured to output light in a direction perpendicular to the surface of the substrate 100, and the other of the plurality of emission portions EP1, EP2, and EP3 can be configured to output light in a direction which is inclined with respect to the surface of the substrate 100 (e.g., in a diagonal direction).

The emission portion EP of each of the first to fourth subpixels SP1 to SP4 according to an embodiment of the present disclosure can include first to third emission portions EP1, EP2, and EP3. For example, each of the first to fourth subpixels SP1 to SP4 can include the first emission portion EP1 disposed at a first region of the subpixel areas SPA1 to SPA4, the second emission portion EP2 disposed at a second region of the subpixel areas SPA1 to SPA4, and the third emission portion EP3 disposed at a third region of the subpixel areas SPA1 to SPA4. For example, in each of the subpixel areas SPA1 to SPA4, the first region can be a center region or a middle region, the second region can be one edge region, a first edge region, or one region of the first region, and the third region can be the other edge region, a second edge region, or the other region of the first region.

Each of the first to third emission portions EP1, EP2, and EP3 can have a width parallel to the first direction X and a length parallel to the second direction Y. For example, a short side of each of the first to third emission portions EP1, EP2, and EP3 can be parallel to a horizontal direction of the display panel 10 or the substrate 100. A long side of each of the first to third emission portions EP1, EP2, and EP3 can be parallel to a vertical direction of the display panel 10 or the substrate 100. The first to third emission portions EP1, EP2, and EP3 can be arranged (or disposed or configured) in parallel. The first emission portion EP1 can be disposed between the second emission portion EP2 and the third emission portion EP3. The second emission portion EP2 and the third emission portion EP3 can be disposed (or configured) in parallel with the first emission portion EP1 therebetween and can be disposed (or configured) to be inclined with respect to the substrate 100.

Some of the first, second and third emission portions EP1, EP2, and EP3 can have different sizes and shapes (or areas). For example, the first emission portion EP1 can have a size which is greater than each of the second emission portion EP2 and the third emission portion EP3. The second emission portion EP2 and the third emission portion EP3 can have the same size (or area), but is not limited thereto. For example, the first emission portion EP1 can have a size which is equal to a sum of a size of the second emission portion EP2 and a size of the third emission portion EP3, or can have a size which is greater than the sum of a size of the second emission portion EP2 and a size of the third emission portion EP3. Also, an area of the second emission portion EP2 can be equal to or substantially equal to an area of the of the third emission portion EP3 and they can have a same shape, but embodiments are not limited thereto. For example, the second emission portion EP2 and the third emission portion EP3 can have different areas and different shapes than each other.

According to an embodiment of the present disclosure, the first emission portion EP1 can be disposed (or configured) to face or be parallel to a surface (or front surface or light output surface) of the substrate 100. A light extraction surface (or an emission surface) of the first emission portion EP1 can be disposed (or configured) to face or be parallel to a surface of the substrate 100. The first emission portion EP1 can be configured to output light in a direction perpendicular to the surface (or front surface or light output surface) of the substrate 100.

Each of the second and third emission portions EP2 and EP3 can be inclined or sloped from the first emission portion EP1. Each of the second emission portion EP2 and the third emission portion EP3 can be inclined or sloped with respect to the substrate 100. Each of the second and third emission portions EP2 and EP3 can be sloped or inclined by the same angle from the first emission portion EP1, but embodiments are not limited thereto. For example, according to another embodiment, the second and third emission portions EP2 and EP3 can have different angles of inclination (e.g., different slopes). The light extraction surface (or emission surface) of each of the second emission portion EP2 and the third emission portion EP3 can be inclined or sloped from the light extraction surface (or emission surface) of the first emission portion EP1. The light extraction surface (or emission surface) of each of the second emission portion EP2 and the third emission portion EP3 can be inclined or sloped with respect to the surface (or front surface or light output surface) of the substrate 100. Each of the second emission portion EP2 and the third emission portion EP3 can be configured to output light in a direction which is sloped or inclined with respect to the surface (or front surface or light output surface) of the substrate 100 (e.g., in a diagonal direction).

According to an embodiment of the present disclosure, the first emission portion EP1 can be a main emission portion, a front emission portion, a flat emission portion, or a center emission portion. The second emission portion EP2 can be a first sub emission portion, a first lateral emission portion, a first slope emission portion (or first oblique emission portion), a first view emission portion, or a first edge emission portion. The third emission portion EP3 can be a second sub emission portion, a second lateral emission portion, a second slope emission portion (or second oblique emission portion), a second view emission portion, or a second edge emission portion.

According to an embodiment of the present disclosure, each of the plurality of first to fourth subpixels SP1 to SP4 can include a pixel electrode PE which is disposed at each of the subpixel areas SPA1 to SPA4.

The pixel electrode PE can include a plurality of first to third pixel electrodes PE1, PE2, and PE3 which are disposed in parallel in (or within) the subpixel areas SPA1 to SPA4. The plurality of first to third emission portions EP1, EP2, and EP3 can be implemented (or configured) by the plurality of first to third pixel electrodes PE1, PE2, and PE3. For example, the first emission portion EP1 can correspond to the first pixel electrode PE1, the second emission portion EP2 can correspond to the second pixel electrode PE2, and the third emission portion EP3 can correspond to the third pixel electrode PE3.

The plurality of first to third pixel electrodes PE1, PE2, and PE3 can be separated or spaced apart from one another by a plurality of slits SL1 and SL2, in (or within) the emission area EA of each of the subpixel areas SPA1 to SPA4. For example, a first slit SL1 can be disposed (or configured) between the first pixel electrode PE1 and the second pixel electrode PE2, and a second slit SL2 can be disposed (or configured) between the first pixel electrode PE1 and the third pixel electrode PE3.

One end of each of the plurality of first to third pixel electrodes PE1, PE2, and PE3 can be electrically connected to an electrode connection line ECL. For example, each of the plurality of first to third pixel electrodes PE1, PE2, and PE3 can protrude or extend from the electrode connection line ECL, in (or within) the subpixel areas SPA1 to SPA4 (e.g., finger electrodes extending from the electrode connection line ECL). The electrode connection line ECL can be connected to the one end of each of the plurality of first to third pixel electrodes PE1, PE2, and PE3 in common. For example, the electrode connection line ECL can be disposed (or configured) in the circuit area CA.

Each of the plurality of first to fourth subpixels SP1 to SP4 can include a pixel circuit PC which is disposed (or configured) on the substrate 100 of the circuit area CA.

The pixel circuit PC configured at each of the plurality of first to fourth subpixels SP1 to SP4 can be configured to supply a data current to the plurality of first to third pixel electrodes PE1, PE2, and PE3 disposed at corresponding subpixels SP1 to SP4. For example, the pixel circuit PC can be configured to simultaneously supply the data current to the plurality of first to third pixel electrodes PE1, PE2, and PE3.

The pixel circuit PC can be configured to be connected to a corresponding gate line GL, a corresponding driving voltage line PL, corresponding data lines DL1 to DL4, and a corresponding reference voltage line RL. For example, the pixel circuit PC can be electrically connected to the driving voltage line PL through a power connection line PCL and can be electrically connected to the reference voltage line RL through a reference power connection line RCL.

The pixel circuit PC can be configured to supply a data current, corresponding to a data voltage supplied through each of corresponding data lines DL1 to DL4, to a corresponding plurality of first to third pixel electrodes PE1, PE2, and PE3 in response to the gate signal supplied to a corresponding gate line GL. Accordingly, the plurality of first to third emission portions EP1, EP2, and EP3 can individually emit light or simultaneously emit light with a data current supplied to the plurality of first to third pixel electrodes PE1, PE2, and PE3, according to embodiments.

Each of the plurality of gate lines GL can be connected to the pixel circuit PC configured in each of the plurality of first to fourth subpixels SP1 to SP4 in common. The plurality of data lines DL1 to DL4 can be respectively disposed in the plurality of first to fourth subpixels SP1 to SP4 and can be connected to a corresponding pixel circuit PC. For example, each of the plurality of first to fourth subpixels SP1 to SP4 can include one pixel circuit PC, one gate line GL, and one data line DL.

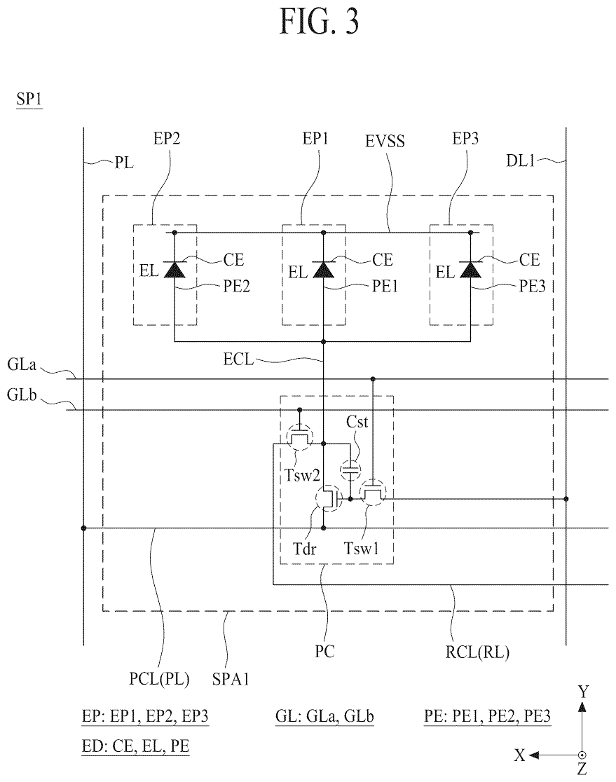

FIG. 3 is an equivalent circuit view illustrating a first subpixel illustrated in FIG. 2.

Referring to FIGS. 2 and 3, a first subpixel SP1 according to an embodiment of the present disclosure can include an emission portion EP, including a light emitting device ED, and a pixel circuit PC electrically connected to the light emitting device ED.

The emission portion EP can include a plurality of first, second and third emission portions EP1, EP2, and EP3 including the light emitting device ED. Each of the plurality of first, second and third emission portions EP1, EP2, and EP3 can include the light emitting device ED.

The light emitting device ED of each of the plurality of first, second and third emission portions EP1, EP2, and EP3 can include a pixel electrode PE, an emission layer EL on the pixel electrode PE, and a common electrode (or a cathode electrode) CE on the emission layer EL. For example, the light emitting device ED of the first emission portion EP1 can include a first pixel electrode PE1, the emission layer EL on the first pixel electrode PE1, and the common electrode CE on the emission layer EL. The light emitting device ED of the second emission portion EP2 can include a second pixel electrode PE2, the emission layer EL on the second pixel electrode PE2, and the common electrode CE on the emission layer EL. The light emitting device ED of the third emission portion EP3 can include a third pixel electrode PE3, the emission layer EL on the third pixel electrode PE3, and the common electrode CE on the emission layer EL.

According to an embodiment of the present disclosure, the emission layer EL of the light emitting device ED can be a common layer which is disposed (or configured) in the plurality of first, second and third emission portions EP1, EP2, and EP3 in common. Accordingly, a light emitting device ED configured in a first subpixel SP1 (or each of the plurality of subpixels SP1 to SP4) can include a plurality of first, second and third pixel electrodes PE1, PE2, and PE3, an emission layer EL on the plurality of first, second and third pixel electrodes PE1, PE2, and PE3, and a common electrode CE on the emission layer EL.

According to another embodiment of the present disclosure, the emission layer EL of the light emitting device ED can be an organic emission layer, a quantum dot emission layer, or an inorganic emission layer. For example, the emission layer EL can include a hole function layer, an organic emission layer disposed on the hole function layer, and an electron function layer disposed on the organic emission layer. For example, the emission layer EL of the light emitting device ED can be changed to an inorganic light emitting diode or a micro light emitting diode.

The pixel circuit PC according to another embodiment of the present disclosure can include a first switching transistor Tsw1, a second switching transistor Tsw2, a driving transistor Tdr, and a storage capacitor Cst.

Each of the transistors Tsw1, Tsw2 and Tdr of the pixel circuit PC can be comprised of a thin-film transistor (TFT), and at least one of the thin-film transistors Tsw1, Tsw2 and Tdr can be a-Si TFT, a poly-Si TFT, an Oxide TFT, or an Organic TFT. For example, in the pixel circuit PC, some of the first switching transistor Tsw1, the second switching transistor Tsw2 and the driving transistor Tdr can be a thin-film transistor that includes a semiconductor layer (or active layer) made of low-temperature poly-Si (LTPS) having an excellent response characteristic, and the other of the first switching transistor Tsw1, the second switching transistor Tsw2 and the driving transistor Tdr can be a thin-film transistor that includes a semiconductor layer (or active layer) made of oxide having an excellent off current characteristic.

The first switching transistor Tsw1 can include a gate electrode (or control electrode) that is connected to the first gate line GLa, a first electrode that is connected to the data line DL adjacent thereto, and a second electrode that is connected to the gate electrode of the driving transistor Tdr. The gate electrode of the first switching transistor Tsw1 can be a protrusion area protruded from one side of the first gate line GLa. The first switching transistor Tsw1 can be turned on in accordance with a first gate signal supplied to the first gate line GLa and supply the data voltage supplied from the adjacent data line DL to the gate electrode of the driving transistor Tdr. For example, in the first switching transistor Tsw1, the first electrode can be a source electrode and the second electrode can be a drain electrode, but is not limited thereto, the first electrode can be a drain electrode and the second electrode can be a source electrode.

The second switching transistor Tsw2 can include a gate electrode (or control electrode) that is connected to the second gate line GLb, a first electrode that is connected to the source electrode of the driving transistor Tdr, and a second electrode that is connected to the reference voltage line RL adjacent thereto. The second switching transistor Tsw2 can supply the reference voltage supplied from the reference voltage line RL to the source electrode of the driving transistor Tdr in accordance with a second gate signal supplied to the second gate line GLb in the display mode. In addition, the second switching transistor Tsw2 can be turned on in accordance with a second gate signal supplied to the second gate line GLb in the sensing mode and supply a current output from the driving transistor Tdr to the adjacent reference voltage line RL or connect the source electrode of the driving transistor Tdr to the adjacent reference voltage line RL. For example, in the second switching transistor Tsw2, the first electrode can be a source electrode and the second electrode can be a drain electrode, but is not limited thereto, the first electrode can be a drain electrode and the second electrode can be a source electrode.

The storage capacitor Cst can be formed between the gate electrode and the source electrode of the driving transistor Tdr. The storage capacitor Cst can include a first capacitor electrode provided with the gate electrode GE of the driving transistor Tdr, a second capacitor electrode made of the source electrode of the driving transistor Tdr, and a dielectric layer formed at an overlap area between the first capacitor electrode and the second capacitor electrode. The storage capacitor Cst can charge (or store) a differential voltage between the gate electrode and the source electrode of the driving transistor Tdr and turns on the driving transistor Tdr in accordance with the charged voltage.

The driving transistor Tdr can include the gate electrode that is connected to the second electrode of the first switching transistor Tsw1, the source electrode that is connected to the first electrode of the second switching transistor Tsw2, and the drain electrode that is connected to the pixel driving voltage line PL. The source electrode of the driving transistor Tdr can be electrically connected to the first to third pixel electrodes PE1, PE2, and PE3 through the electrode connection line ECL. Accordingly, the driving transistor Tdr is turned on in accordance with the voltage of the storage capacitor Cst and controls the amount of a current flowing from the pixel driving voltage line PL to the light emitting device ED.

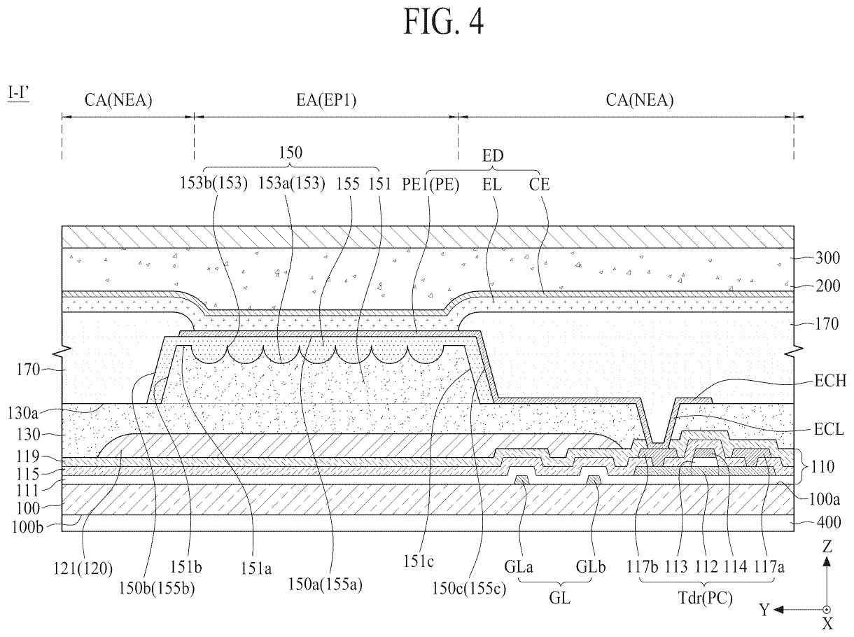

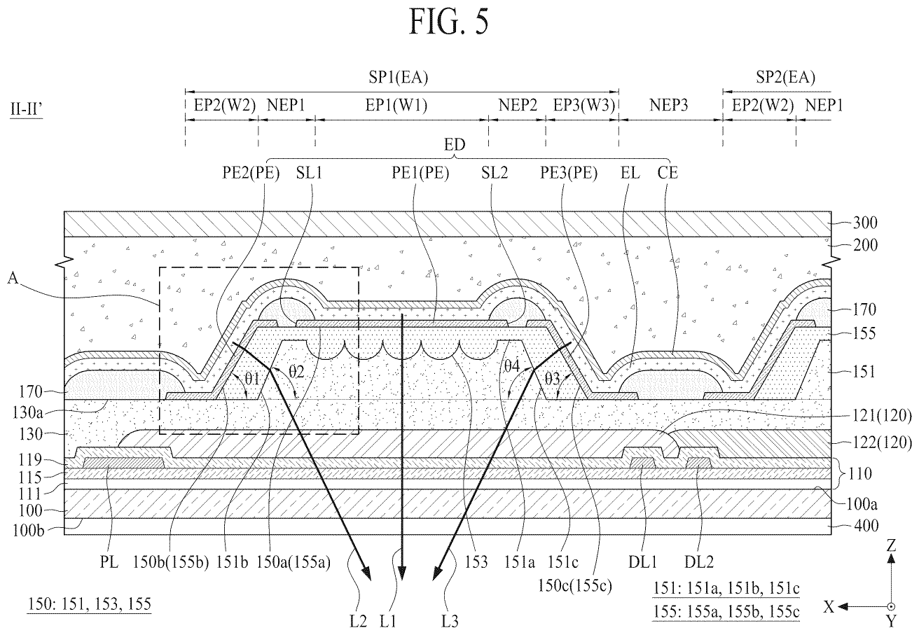

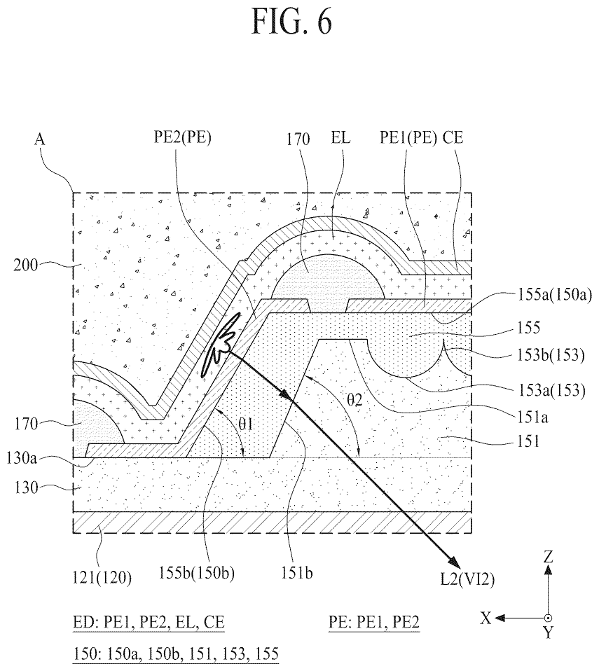

FIG. 4 is a cross-sectional view taken along line I-I′ illustrated in FIG. 2 according to an embodiment of the present disclosure, FIG. 5 is a cross-sectional view taken along line II-II′ illustrated in FIG. 2 according to an embodiment of the present disclosure, and FIG. 6 is an enlarged view of part “A” illustrated in FIG. 5 according to an embodiment of the present disclosure.

Referring to FIGS. 2, 4, and 5, the light emitting display apparatus (or light emitting display panel) according to an embodiment of the present disclosure can include a pixel circuit layer 110, a protection layer 130, a pattern portion 150, and a light emitting device ED which are disposed over the substrate 100.

The pixel circuit layer 110 can include a buffer layer 111, a pixel circuit PC, and a passivation layer 119.

The buffer layer 111 can be disposed at an entire first surface 100a of the substrate 100 (e.g., top surface of the substrate 100). The buffer layer 111 can prevent or at least reduce materials contained in the substrate 100 from spreading to a transistor layer during a high-temperature process in the manufacturing of the thin film transistor (e.g., prevent outgassing), or can prevent external water or moisture from permeating into the light emitting device ED. For example, the buffer layer 111 can be made of an inorganic insulating material.

The pixel circuit PC can include a driving transistor (for example, a driving thin film transistor) Tdr disposed in a circuit area CA of each subpixel SP (or each subpixel areas SPA). The driving transistor Tdr can include an active layer 112, a gate insulating layer 113, a gate electrode 114, an interlayer insulating layer 115, a drain electrode 117a, and a source electrode 117b.

The active layer 112 can be configured with a semiconductor material based on any one of amorphous silicon, polycrystalline silicon, oxide, and organic materials. The active layer 112 can include a channel region, a drain region, and a source region.

The gate insulating layer 113 can be formed over a channel region of the active layer 112. In an embodiment, the gate insulating layer 113 can be formed to have an island shape over the channel region of the active layer 112, or can be formed (or configured) over an entire front surface of the buffer layer 111 or the substrate 100 including the active layer 112. For example, the gate insulating layer 113 can be made of an inorganic insulating material.

The gate electrode 114 can be formed (or configured) over a gate insulating layer 114 to overlap the channel region of an active layer 112.

The interlayer insulating layer 115 can be formed (or configured) over the gate electrode 114, and the drain region and the source region of the active layer 112. The interlayer insulating layer 115 can be formed (or configured) to cover the gate electrode 114, and the drain region and the source region of the active layer 112. For example, the interlayer insulating layer 115 can be formed (or configured) at an entire front surface of the buffer layer 111 or the substrate 100. For example, the interlayer insulating layer 115 can be made of an inorganic insulating material.

The drain electrode 117a can be formed (or configured) over the interlayer insulating layer 115 to be electrically connected to the drain region of the active layer 112. The source electrode can be formed (or configured) over the interlayer insulating layer 115 to be electrically connected to the source region of the active layer 1122.

The pixel circuit PC can further include the first switching transistor (for example, a first switching thin film transistor), the second switching transistor (for example, a second switching thin film transistor), and the storage capacitor Cst described with reference to FIG. 3. The first switching transistor, the second switching transistor, and the storage capacitor Cst can be formed (or configured) at the circuit area CA together with the driving transistor Tdr.

The passivation layer 119 can be formed (or configured) over the substrate 100 to cover the pixel circuit PC. For example, the passivation layer 119 can be formed (or configured) to cover the drain electrode 117a and the source electrode 117b of the driving transistor Tdr and the interlayer insulating layer 115. For example, the passivation layer 119 can be made of an inorganic insulating material.

The protection layer 130 can be formed (or configured) over the substrate 100 to cover the pixel circuit layer 110 or the passivation layer 119. The protection layer (e.g., planarization layer) 130 can be formed (or configured) to have a relatively large thickness, and can provide a planarized surface (or a planarization surface or flat surface) 130a over the pixel circuit layer 110 or the passivation layer 119. For example, the protection layer 130 can be made of an organic material such as photo acrylic, benzocyclobutene, polyimide, and fluorine resin. The protection layer 130 can be an insulating layer, an organic material layer, an uppermost insulating layer, a planarization layer, or an overcoat layer.

The pattern portion 150 can be formed (or configured) over the protection layer 130 in the emission area EA of each of the plurality of subpixels SP1 to SP4. The pattern portion 150 can be formed (or configured) over a flat surface 130a of the protection layer 130 in the emission area EA of each of the plurality of subpixels SP1 to SP4. For example, the pattern portion 150 can be formed (or configured) over the flat surface 130a of the protection layer 130 in the emission area EA to have a flat surface and a slope surface. For example, the pattern portion 150 can include a cross-sectional structure having a trapezoid shape or a mesa shape.

The pattern portion 150 according to an embodiment of the present disclosure can include a first surface 150a, a second surface 150b, and a third surface 150c.

The first surface 150a can be a top surface, an upper surface, or an uppermost surface of the pattern portion 150. For example, the first surface 150a can be a flat surface or a flat structure parallel to a first surface 100a of the substrate 100. The first surface 150a can be disposed (or configured) at a center region of the emission area EA.

The second surface 150b can be disposed (or configured) at a first side of the first surface 150a. The second surface 150b can have a cross-sectional structure which differs from the first surface 150a. The second surface 150b can be a slope surface which is sloped or inclined from the first side of the first surface 150a. For example, an angle (or an interior angle) between the second surface 150b and the first surface 150a can be an obtuse angle. For example, an angle (or an interior angle) between the second surface 150b and the upper surface (or flat surface) 130a of the protection layer 130 can be an acute angle. The second surface 150b can be inclined or sloped with respect to the first surface 100a of the substrate 100. The second surface 150b can be disposed (or configured) at one region or a first edge region of the emission area EA. For example, the second surface 150b can be one surface, one slope surface, or a first slope surface of the pattern portion 150.

The third surface 150c can be disposed (or configured) at a second side, which is different from or opposite to the first side, of the first surface 150a. The third surface 150c can have a cross-sectional structure which differs from the first surface 150a. The third surface 150c can be a slope surface which is sloped or inclined from the second side of the first surface 150a. For example, an angle (or an interior angle) between the third surface 150c and the first surface 150a can be an obtuse angle. For example, an angle (or an interior angle) between the third surface 150c and the upper surface (or flat surface) 130a of the protection layer 130 can be an acute angle. The third surface 150c can be inclined or sloped with respect to the first surface 100a of the substrate 100. The third surface 150c can be disposed (or configured) at the other region or a second edge region of the emission area EA. For example, the second surface 150b and the third surface 150c can have a symmetric structure with respect to the first surface 150a. For example, the third surface 150c can be the other surface, the other slope surface, or a second slope surface of the pattern portion 150.

According to an embodiment of the present disclosure, the emission area EA of each of the plurality of subpixels SP1 to SP4 can include first to third regions by the pattern portion 150. For example, the emission area EA can include a first region corresponding to (or overlapping) the first surface 150a of the pattern portion 150, a second region corresponding to (or overlapping) the second surface 150b of the pattern portion 150, and a third region corresponding to (or overlapping) the third surface 150c of the pattern portion 150. For example, in the emission area EA, the first region can be a main region, a center region, or a middle region, the second region can be a first sub region, one region, or a first edge region, and the third region can be a second sub region, the other region, or a second edge region.

The pattern portion 150 according to an embodiment of the present disclosure can include a first pattern layer 151 and a second pattern layer 155.

The first pattern layer 151 can be formed (or configured) over the protection layer 130. The first pattern layer 151 can be formed (or configured) over the flat surface 130a of the protection layer 130 in the emission area EA to include a flat surface and a slope surface. For example, the first pattern layer 151 can protrude from the flat surface 130a of the protection layer 130 to include a flat surface and a slope surface. For example, the pattern portion 150 can protrude from the flat surface 130a of the protection layer 130 to include a cross-sectional structure having a trapezoid shape or a mesa shape. For example, the first pattern layer 151 can be formed (or configured) of a same material as the protection layer 130, but is not limited thereto. For example, the first pattern layer 151 can be a protrusion portion or a protrusion pattern portion.

The first pattern layer 151 according to an embodiment of the present disclosure can include a light extraction surface 151a, a first lateral surface 151b, and a second lateral surface 151c.

The light extraction surface 151a can be a flat surface or a flat structure parallel to a first surface 100a of the substrate 100. The light extraction surface 151a can be disposed (or configured) at the center region of the emission area EA. For example, the light extraction surface 151a can be a protrusion surface, an upper protrusion surface, a first protrusion surface, a light extraction portion, a light scattering portion, or a light scattering surface.

The first lateral surface 151b can be disposed (or configured) at a first side of the light extraction surface 151a. The first lateral surface 151b can have a cross-sectional structure which differs from the light extraction surface 151a. The first lateral surface 151b can be a slope surface which is sloped or inclined from the first side of the light extraction surface 151a. For example, an angle (or an interior angle) between the first lateral surface 151b and the light extraction surface 151a can be an obtuse angle. For example, an angle (or an interior angle) between the first lateral surface 151b and the upper surface (or flat surface) 130a of the protection layer 130 can be an acute angle. The first lateral surface 151b can be inclined or sloped with respect to the first surface 100a of the substrate 100. The first lateral surface 151b can be disposed (or configured) at one region or a first edge region of the emission area EA. For example, the first lateral surface 151b can be one surface, one slope surface, a first slope surface, one protrusion surface, or a first light refraction surface of the first pattern layer 151.

The second lateral surface 151c can be disposed (or configured) at a second side, which is different from or opposite to the first side, of the light extraction surface 151a. The second lateral surface 151c can have a cross-sectional structure which differs from the light extraction surface 151a. The second lateral surface 151c can be a slope surface which is inclined or sloped from the second side of the light extraction surface 151a. For example, an angle (or an interior angle) between the second lateral surface 151c and the light extraction surface 151a can be an obtuse angle. For example, an angle (or an interior angle) between the second lateral surface 151c and the upper surface (or flat surface) 130a of the protection layer 130 can be an acute angle. The second lateral surface 151c can be inclined or sloped with respect to the first surface 100a of the substrate 100. The second lateral surface 151c can be disposed (or configured) at the other region or a second edge region of the emission area EA. For example, the first lateral surface 151b and the second lateral surface 151c can have a symmetric structure with respect to the light extraction surface 151a. The second lateral surface 151c can be the other surface, the other slope surface, a second slope surface, the other protrusion surface, or a second light refraction surface of the first pattern layer 151.

The light extraction surface 151a of the first pattern layer 151 can be formed (or configured) as a non-flat surface. For example, the first pattern layer 151 can further include a non-flat portion 153 which is formed (or configured) at the light extraction surface 151a. For example, the light extraction surface 151a or the non-flat portion 153 can be an uneven pattern portion, a micro lens portion, or a light scattering pattern. For example, the light extraction surface 151a or the non-flat portion 153 can include a plurality of concave portions that are configured to redirect light emitted from the emitting layer in a direction perpendicular to the substrate (e.g., in a direction that is more straight into a user's eyes), as discussed in more detail below. For example, first pattern layer 151 and the second pattern layer 155 can have different indexes of refraction, discussed in more detail below.

The non-flat portion 153 can include a plurality of concave portions 153a. For example, the non-flat portion 153 can include a plurality of concave portions 153a and a convex portion 153b disposed around each of the plurality of concave portions 153a. The plurality of concave portions 153a can be formed or configured to be concave from the light extraction surface 151a. The convex portion 153b can be disposed between the plurality of concave portions 153a. The convex portion 153b can be formed to surround each of the plurality of concave portions 153a.

According to an embodiment of the present disclosure, the plurality of concave portions 153a can be disposed or arranged in a honeycomb structure in a plan view or a circular structure. Each of the plurality of concave portions 153a can be formed (or configured) as a parabola shape. For example, each of the plurality of concave portions 153a can be a parabolic or parabolic structure.

According to an embodiment of the present disclosure, an upper portion of the convex portion 153b can include a sharp structure or a pointed portion, but is not limited thereto. For example, the upper portion of the convex portion 153b can have a convex curved shape (or curved surface). For example, the upper portion of the convex portion 153b can include a dome or bell structure with a convex cross-section, but is not limited thereto. For example, according to another embodiment, the upper portion of the convex portion 153b can have a rounded tip or a blunt portion.

The second pattern layer 155 can be formed (or configured) to surround the first pattern layer 151. The second pattern layer 155 can be formed (or configured) to cover the first pattern layer 151. The second pattern layer 155 can be formed (or configured) over the protection layer 130 to cover or surround the first pattern layer 151. The second pattern layer 155 can be formed (or configured) over the flat surface 130a of the protection layer 130 to cover or surround the first pattern layer 151. For example, a size (or area) of the second pattern layer 155 can be greater than the first pattern layer 151. For example, the second pattern layer 155 can directly contact the light extraction surface 151a, the first lateral surface 151b, and the second lateral surface 151c of the first pattern layer 151 and can directly contact the flat surface 130a of the protection layer 130 at a periphery of the first pattern layer 151. For example, the second pattern layer 155 can surround and enclose the first pattern layer 151, but embodiments are not limited thereto.

The second pattern layer 155 according to an embodiment of the present disclosure can include an upper surface 155a, a first slope surface 155b, and a second slope surface 155c.

The upper surface 155a can be formed (or configured) over the light extraction surface 151a of the first pattern layer 151. The upper surface 155a can be spaced apart from the light extraction surface 151a of the first pattern layer 151. The light extraction surface 151a of the first pattern layer 151 can be formed (or configured) under (or below) the upper surface 155a of the second pattern layer 155. For example, the upper surface 155a of the second pattern layer 155 can cover the light extraction surface 151a of the first pattern layer 151 and can provide a flat surface over the light extraction surface 151a of the first pattern layer 151. The upper surface 155a of the second pattern layer 155 and the light extraction surface 151a of the first pattern layer 151 can have different cross-sectional structures. For example, the upper surface 155a of the second pattern layer 155 can be configured as a flat surface or in a flat structure, and the light extraction surface 151a of the first pattern layer 151 can be configured in a non-flat structure or a concave-convex surface (or an uneven surface, or a dimpled surface).

The first slope surface 155b can be formed (or configured) to cover the first lateral surface 151b of the first pattern layer 151. The first slope surface 155b can be spaced apart from the first lateral surface 151b of the first pattern layer 151. For example, an angle (or an interior angle) between the first slope surface 155b and the upper surface 155a can be an obtuse angle. For example, an angle (or an interior angle) between the first slope surface 155b and the upper surface (or flat surface) 130a of the protection layer 130 can be an acute angle. For example, an angle between the first slope surface 155b and the upper surface 130a of the protection layer 130 can be smaller than or equal to an angle between the first lateral surface 151b of the first pattern layer 151 and the upper surface 130a of the protection layer 130.

The second slope surface 155c can be formed (or configured) to cover the second lateral surface 151c of the first pattern layer 151. The second slope surface 155c can be spaced apart from the second lateral surface 151c of the first pattern layer 151. For example, an angle (or an interior angle) between the second slope surface 155c and the upper surface 155a can be an obtuse angle. For example, an angle (or an interior angle) between the second slope surface 155c and the upper surface (or flat surface) 130a of the protection layer 130 can be an acute angle. For example, an angle between the second slope surface 155c and the upper surface 130a of the protection layer 130 can be smaller than or equal to an angle between the second lateral surface 151c of the first pattern layer 151 and the upper surface 130a of the protection layer 130.

The first pattern layer 151 and the second pattern layer 155 can be formed (or configured) to have different refractive indexes. The first pattern layer 151 and the second pattern layer 155 can be formed (or configured) of organic materials having different refractive indexes. For example, a refractive index of the second pattern layer 155 can be higher than that of the first pattern layer 151 (e.g., R index of the second pattern layer 155>R index of the first pattern layer 151). For example, the second pattern layer 155 can be formed (or configured) by an organic material or a material having a refractive index which is higher than that of the first pattern layer 151. For example, the first pattern layer 151 can be a low refraction layer or a low refraction pattern layer. The second pattern layer 155 can be a high refraction layer or a high refraction pattern layer.

The light emitting device ED can be formed (or configured) over the pattern portion 150. The light emitting device ED can be formed (or configured) over the pattern portion 150 and the protection layer 130. For example, the light emitting device ED can be configured to emit light toward the substrate 100 according to a bottom emission type, but embodiments according to the present disclosure are not limited thereto. For example, the light emitting device ED can be a light emitting device layer or a common emission layer (or common light emitting layer).

The light emitting device ED according to an embodiment of the present disclosure can include a pixel electrode PE, an emission layer EL, and a common electrode CE. For example, the pixel electrode PE can be a first electrode, an anode electrode, or a transparent pixel electrode. The common electrode CE can be a second electrode, a cathode electrode, a counter electrode (or opposite electrode), or reflective electrode.

The pixel electrode PE can be formed (or configured) over the pattern portion 150. The pixel electrode PE can be formed (or configured) over the pattern portion 150 and can be formed (or configured) over a portion of the protection layer 130 adjacent to the pattern portion 150. The pixel electrode PE can be electrically connected to a source electrode 117b (or a drain electrode 117a) of the driving transistor Tdr. One end of the pixel electrode PE which is close to the circuit area CA can be electrically connected to the source electrode 117b of the driving transistor Tdr through an electrode contact hole ECH provided at the protection layer 130 and the passivation layer 119.

According to an embodiment of the present disclosure, the pixel electrode PE in the emission area EA of each of the plurality of subpixels SP1 to SP4 can include first, second and third pixel electrodes PE1, PE2, and PE3.

The first pixel electrode PE1 can be formed (or configured) over the first surface (or upper surface) 150a of the pattern portion 150. The first pixel electrode PE1 can have a size smaller than a size of the first surface 150a of the pattern portion 150. For example, the first pixel electrode PE1 can be formed (or configured) at the other portion, except an edge portion, of the first surface 150a of the pattern portion 150. The first pixel electrode PE1 can be formed (or configured) to be parallel to the first surface 100a of the substrate 100. For example, the first pixel electrode PE1 can have a flat structure where the first surface 150a is parallel to the first surface 100a of the substrate 100. The first pixel electrode PE1 can be formed (or configured) at a center region of the emission area EA to have a plate shape.

The second pixel electrode PE2 can be formed (or configured) over the second surface (or first slope surface) 150b of the pattern portion 150. The second pixel electrode PE2 can have a size greater than a size of the second surface 150b of the pattern portion 150. For example, a first edge portion of the second pixel electrode PE2 adjacent to the first pixel electrode PE1 can contact (or directly contact) one edge portion of the first surface 150a of the pattern portion 150. The first edge portion of the second pixel electrode PE2 can be spaced apart from the first pixel electrode PE1. For example, a second edge portion, which is opposite to the first edge portion, of the second pixel electrode PE2 can contact (or directly contact) a portion of the protection layer 130 adjacent to the pattern portion 150. A center portion between the first edge portion and the second edge portion of the second pixel electrode PE2 can contact (or directly contact) the second surface 150b of the pattern portion 150 and can be inclined or sloped with respect to the first pixel electrode PE1. For example, the second pixel electrode PE2 can have a main diagonal portion (e.g., inclined part), an upper bent portion and a lower bent portion, in which the upper and lower bent portions can extend parallel to the substrate.

The third pixel electrode PE3 can be formed (or configured) over the third surface (or second slope surface) 150c of the pattern portion 150. The third pixel electrode PE3 can have a size greater than a size of the third surface 150c of the pattern portion 150. For example, a first edge portion of the third pixel electrode PE3 adjacent to the first pixel electrode PE1 can contact (or directly contact) the other edge portion of the first surface 150a of the pattern portion 150. The first edge portion of the third pixel electrode PE3 can be spaced apart from the first pixel electrode PE1. For example, a second edge portion, which is opposite to the first edge portion, of the third pixel electrode PE3 can contact (or directly contact) a portion of the protection layer 130 adjacent to the pattern portion 150. A center portion between the first edge portion and the second edge portion of the third pixel electrode PE3 can contact (or directly contact) the third surface 150c of the pattern portion 150 and can be inclined or sloped with respect to the first pixel electrode PE1. For example, the third pixel electrode PE3 can have a main diagonal portion (e.g., inclined part), an upper bent portion and a lower bent portion, in which the upper and lower bent portions can extend parallel to the substrate.

According to an embodiment of the present disclosure, the first, second and third pixel electrodes PE1, PE2, and PE3 can be spaced apart from (or electrically disconnected from) one another in the emission area EA and can be commonly connected to the pixel circuit PC in the circuit area CA. For example, the pixel circuit PC configured at each of the plurality of subpixels SP1 to SP4 can include a driving transistor (such as a thin film transistor (TFT)) Tdr which is commonly connected to the first to third pixel electrodes PE1, PE2, and PE3.

According to an embodiment of the present disclosure, one end of each of the first to third pixel electrodes PE1, PE2, and PE3 adjacent to the circuit area CA can be electrically connected to the electrode connection line ECL. The electrode connection line ECL can be electrically connected to a source electrode 117b (or a drain electrode 117a) of the driving transistor Tdr. The electrode connection line ECL can be electrically connected to the source electrode 117b of the driving transistor Tdr through the electrode contact hole ECH provided at the protection layer 130 and the passivation layer 119. Accordingly, each of the first to third pixel electrodes PE1, PE2, and PE3 can be commonly connected to the source electrode 117b of the driving transistor Tdr through the electrode connection line ECL.

The pixel electrode PE or the first, second and third pixel electrodes PE1, PE2, and PE3 and the electrode connection line ECL can be made of a transparent conductive material such as transparent conductive oxide (TCO). For example, the pixel electrode PE or the first, second and third pixel electrodes PE1, PE2, and PE3 and the electrode connection line ECL can include indium tin oxide (ITO) or indium zinc oxide (IZO), but is not limited thereto.

The emission layer EL can be formed (or configured) over the pixel electrode PE. The emission layer EL can be formed (or configured) over the first, second and third pixel electrodes PE1, PE2, and PE3 and can directly contact each of the first, second third pixel electrodes PE1, PE2, and PE3. The emission layer EL can be additionally formed (or configured) on the protection layer 130 as well as the pixel electrode PE or the first to third pixel electrodes PE1, PE2, and PE3. The emission layer EL can be a common layer which is formed (or configured) at each of the plurality of subpixels SP1 to SP4 in common. For example, the emission layer EL can extend continuously across the first, second and third pixel electrodes PE1, PE2, and PE3. Also, the emission layer EL can extend continuously across adjacent subpixels.

The emission layer EL according to an embodiment of the present disclosure can include two or more organic emission layers configured to emit white light. For example, the emission layer EL can include a stack structure in which two or more organic emission layers are stacked on top of each other. For example, the emission layer EL can include a stack structure that a first organic emission layer and a second organic emission layer are stacked. As an embodiment, the emission layer EL can include a first organic emission layer and a second organic emission layer to emit white light by mixing a first light and a second light. For example, the first organic emission layer can include any one of a blue organic emission layer, a green organic emission layer, a red organic emission layer, a yellow organic emission layer, and a yellow-green organic emission layer to emit the first light. For example, the second organic emission layer can include an organic emission layer capable of emitting the second light to obtain white light in the emission layer EL by mixing the first light of a blue organic emission layer, a green organic emission layer, a red organic emission layer, a yellow organic emission layer, or a yellow-green organic emission layer. The emission layer EL according to another embodiment can include any one of a blue organic emission layer, a green organic emission layer, and a red organic emission layer. Additionally, the emission layer EL can include a charge generating layer interposed between the first organic emission layer and the second organic emission layer.

According to another embodiment of the present disclosure, each of the plurality of subpixels SP1 to SP4 can include an emission layer EL formed (or configured) to emit light of different colors. For example, an emission layer EL of the first subpixel SP1 can include a red organic emission layer. An emission layer EL of the second subpixel SP2 can include a blue organic emission layer. An emission layer EL of the third subpixel SP3 can include two or more organic emission layer for emitting white light. An emission layer EL of the fourth subpixel SP4 can include a green organic emission layer.

According to another embodiment of the present disclosure, when each of the plurality of pixels P includes a red subpixel SP1, a blue subpixel SP2, and a green subpixel SP4, the emission layer EL of the red subpixel SP1 can include a red organic emission layer, the emission layer of the blue subpixel SP2 can include a blue organic emission layer, and the emission layer EL of the green subpixel SP4 can include a green organic emission layer.

The common electrode CE can be formed (or configured) over the emission layer EL. The common electrode CE can be formed (or configured) over the emission layer EL and can directly contact the emission layer EL. For example, the common electrode CE can extend continuously across adjacent subpixels.

The common electrode CE according to an embodiment of the present disclosure can include a metal material having a high reflectance to reflect the incident light emitted from the emission layer EL toward the substrate 100. For example, the common electrode CE can include a single-layered structure or multi-layered structure of any one material selected of aluminum (Al), argentums (Ag), molybdenum (Mo), titanium (Ti), or copper (Cu), or alloy of two or more materials selected from aluminum (Al), argentums (Ag), molybdenum (Mo), titanium (Ti), or copper (Cu). For example, the common electrode CE can be formed in a three-layer structure of IZO/MoTi/ITO or ITO/MoTi/ITO, or can be formed in a four-layer structure of ITO/Cu/MoTi/ITO, but embodiments of the present disclosure are not limited thereto.

The light emitting device ED can generate light responsive to current supplied from the pixel circuit PC and thus, can emit light. According to an embodiment of the present disclosure, the pixel electrode PE, the emission layer EL, and the common electrode CE formed over the pattern portion 150 can configure (or implement) the emission portion EP.

The emission portion EP can include a first emission portion (or flat emission portion, or main emission portion) EP1 formed at the first surface (or upper surface) 150a of the pattern portion 150, a second emission portion (or first slope emission portion, or first sub-emission portion) EP2 formed at the second surface (or first slope surface) 150b of the pattern portion 150, and a third emission portion (or second slope emission portion, or second sub-emission portion) EP3 formed at the third surface (or second slope surface) 150c of the pattern portion 150. For example, the first emission portion (or flat emission portion) EP1, the second emission portion (or first slope emission portion) EP2, and the third emission portion (or second slope emission portion) EP3 can be formed (or configured) over the pattern portion 150.

The first emission portion EP1 can include a first pixel electrode PE1, an emission layer EL and a common electrode CE which are formed (or configured) over the first surface (or upper surface) 150a of the pattern portion 150. The first emission portion EP1 can emit light by light emission of the emission layer EL in accordance with a current applied from the pixel circuit PC to the first pixel electrode PE1.

The second emission portion EP2 can include a second pixel electrode PE2, an emission layer EL and a common electrode CE which are formed (or configured) over the second surface (or first slope surface) 150b of the pattern part 150. The second emission portion EP2 can emit light by light emission of the emission layer EL in accordance with a current applied from the pixel circuit PC to the second pixel electrode PE2.

The third emission portion EP3 can include a third pixel electrode PE3, an emission layer EL and a common electrode CE which are formed (or configured) over the third surface (or second slope surface) 150c of the pattern part 150. The third emission portion EP3 can emit light by light emission of the emission layer EL in accordance with a current applied from the pixel circuit PC to the third pixel electrode PE3.

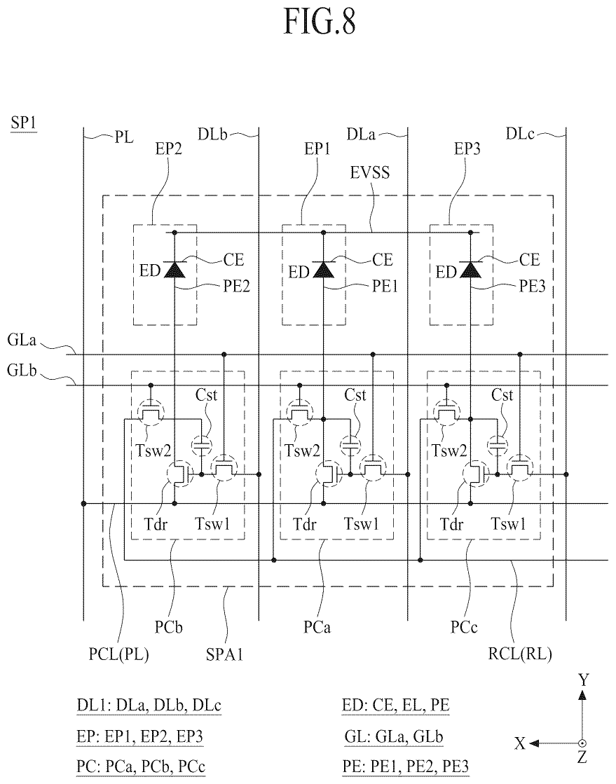

The emission layer EL in each of the first, second, and third emission portions EP1, EP2, and EP3 can simultaneously emit light with a current commonly supplied to the first, second third pixel electrodes PE1, PE2, and PE3 through the electrode connection line ECL from the driving transistor Tdr of the pixel circuit PC. For example, the first, second, and third emission portions EP1, EP2, and EP3 can be wired together so they emit light at a same time, but embodiments are not limited thereto (e.g., see FIG. 8).

According to an embodiment of the present disclosure, the first emission portion EP1 can include the emission layer EL which is disposed (or configured) over the first pixel electrode PE1 having a flat structure, and thus, light (or first light) L1 emitted from the emission layer EL of the first emission portion EP1 can be output in a direction perpendicular to the first surface 100a of the substrate 100. For example, the light L1 emitted from the first emission portion EP1 can be collected and output in the direction perpendicular to the first surface 100a of the substrate 100 by a non-flat portion 153 formed at the first surface 150a of the pattern portion 150. For example, the plurality of concave portions 153a and the convex portions 153b formed at the non-flat portion 153 can collect the light L1, emitted from the first emission portion EP1, in a direction perpendicular to the first surface 100a of the substrate 100 or in a thickness direction Z of the substrate 100. Accordingly, light extraction efficiency corresponding to a front viewing angle can increase based on the light L1 which is emitted from the first emission portion EP1 and is collected and output by the non-flat portion 153.

According to an embodiment of the present disclosure, the second emission portion EP2 can include the emission layer EL which is disposed (or configured) over the second pixel electrode PE2 having a slope structure, and thus, light (or second light) L2 emitted from the emission layer EL of the second emission portion EP2 can be output in a direction which is inclined with respect to the first surface 100a of the substrate 100 (e.g., in a diagonal direction). For example, the light L2 emitted from the second emission portion EP2 can be output by the second surface 150b of the pattern portion 150 in a direction which is inclined with respect to the first surface 100a of the substrate 100. Accordingly, a light output angle of the light L2 emitted from the second emission portion EP2 can differ from that of the light L1 emitted from the first emission portion EP1.

According to an embodiment of the present disclosure, the light L2 emitted from the second emission portion EP2 can be output in a direction which is inclined with respect to the first surface 100a of the substrate 100, based on a refractive index difference between the first slope surface 155b of the second pattern layer 155 in the pattern portion 150 and the first lateral surface 151b of the first pattern layer 151 in the pattern portion 150. Therefore, a viewing angle can be increased or widened by the light L2 which is emitted from the second emission portion EP2 and is output by the first lateral surface 151b and the first slope surface 155b of the pattern portion 150 in a direction which is inclined with respect to the first surface 100a of the substrate 100. Furthermore, the common electrode CE of the second emission portion EP2 can reflect at least portion of the light L1, which is emitted from the first emission portion EP1 and is totally reflected and input by the second pattern layer 155 between the first pixel electrode PE1 and the light extraction surface 151a of the first pattern layer 151 in the pattern portion 150, in a direction which is inclined with respect to the first surface 100a of the substrate 100, and thus, the dissipation of totally reflected light L1 can be minimized (or prevented), thereby increasing the light extraction efficiency of the subpixels SP1 to SP4. Also, color mixing between adjacent subpixels can be prevented or minimized by the inclined structure.

According to an embodiment of the present disclosure, as illustrated in FIG. 6, a first angle (or interior angle) θ1 between the upper surface (or flat surface) 130a of the protection layer 130 and the second surface 150b (or the first slope surface 155b of the second pattern layer 155) of the pattern portion 150 can be an acute angle. A second angle (or interior angle) θ2 between the upper surface (or flat surface) 130a of the protection layer 130 and the first lateral surface 151b of the first pattern layer 151 can be an acute angle. According to an embodiment of the present disclosure, the first angle θ1 can be smaller than or equal to the second angle θ2. For example, the second angle θ2 can be greater than or equal to the first angle θ1 within an acute-angle range (e.g., θ2≥θ1).

According to an embodiment of the present disclosure, the light extraction efficiency of the light L2 emitted from the second emission portion EP2 can be determined based on the first angle θ1 and the second angle θ2. For example, with respect to the light output surface (or light extraction surface) 100b of the substrate 100, the light extraction efficiency of the light L2 emitted from the second emission portion EP2 can be affected by an angle of light emitted from the second emission portion EP2, an angle of light emitted from the second emission portion EP2 to the first pattern layer 151, an angle of light emitted from the first pattern layer 151 to the second pattern layer 155, and an angle of light emitted from the light output surface 100b of the substrate 100 to the outside. For example, the first angle θ1 and the second angle θ2 can be set so that an angle of the light L2, which is emitted from the second emission portion EP2 and is output to the outside of the light output surface 100b of the substrate 100, is greater than 30 degrees and smaller than 45 degrees, and thus, the light extraction efficiency of the light L2 emitted from the second emission portion EP2 can increase or be maximized.

According to an embodiment of the present disclosure, the first angle θ1 can be the same and the second angle θ2 can be the same in each of the plurality of subpixels SP1 to SP4, but embodiments of the present disclosure are not limited thereto. For example, the first angle θ1 can differ and the second angle θ2 can differ in one or more of the plurality of subpixels SP1 to SP4. For example, the first angle θ1 can differ and the second angle θ2 can differ in each of the red subpixel, the blue subpixel, the white subpixel, and the green subpixel. That is, the first angle θ1 can differ and the second angle θ2 can differ for each subpixel.

According to an embodiment of the present disclosure, the third emission portion EP3 can include the emission layer EL which is disposed (or configured) over the third pixel electrode PE3 having a slope structure, and thus, light (or third light) L3 emitted from the emission layer EL of the third emission portion EP3 can be output in a direction which is inclined with respect to the first surface 100a of the substrate 100. For example, the light L3 emitted from the third emission portion EP3 can be output by the third surface 150c of the pattern portion 150 in a direction which is inclined with respect to the first surface 100a of the substrate 100. Accordingly, a light output angle of the light L3 emitted from the third emission portion EP3 can differ from the light L1 emitted from that of the first emission portion EP1.

According to an embodiment of the present disclosure, the light L2 emitted from the third emission portion EP3 can be output in a direction which is inclined with respect to the first surface 100a of the substrate 100, based on a refractive index difference between the second slope surface 155c of the second pattern layer 155 in the pattern portion 150 and the second lateral surface 151c of the first pattern layer 151 in the pattern portion 150. Therefore, a viewing angle can be increased or widened by the light L3 which is emitted from the third emission portion EP3 and is output by the second lateral surface 151c and the second slope surface 155c of the pattern portion 150 in a direction which is inclined with respect to the first surface 100a of the substrate 100. Furthermore, the common electrode CE of the third emission portion EP3 can reflect at least portion of the light L1, which is emitted from the first emission portion EP1 and is totally reflected and input by the second pattern layer 155 between the first pixel electrode PE1 and the light extraction surface 151a of the first pattern layer 151 in the pattern portion 150, in a direction which is inclined with respect to the first surface 100a of the substrate 100, and thus, the dissipation of totally reflected light L1 can be minimized (or prevented), thereby increasing the light extraction efficiency of the subpixels SP1 to SP4. Also, color mixing between adjacent subpixels can be prevented or minimized by the inclined structure.

According to an embodiment of the present disclosure, a third angle (or interior angle) θ3 between the upper surface (or flat surface) 130a of the protection layer 130 and the third surface 150c (or the second slope surface 155c of the second pattern layer 155) of the pattern portion 150 can be an acute angle. A fourth angle (or interior angle) θ4 between the upper surface (or flat surface) 130a of the protection layer 130 and the second lateral surface 151c of the first pattern layer 151 can be an acute angle. According to an embodiment of the present disclosure, the third angle θ3 can be equal to or different from the first angle θ1 described above with reference to FIG. 6, and the fourth angle θ4 can be equal to or different from the second angle θ2 described above with reference to FIG. 6. The third angle θ3 can be smaller than or equal to the fourth angle θ4 (e.g., θ4≥θ3). For example, the fourth angle θ4 can be greater than the third angle θ3 within an acute-angle range. For example, like the first angle θ1 and the second angle θ2 described above with reference to FIG. 6, the third angle θ3 and the fourth angle θ4 can be set so that an angle of the light L3, which is emitted from the third emission portion EP3 and is output to the outside of the light output surface 100b of the substrate 100, is greater than 30 degrees and smaller than 45 degrees, and thus, the light extraction efficiency of the light L3 emitted from the third emission portion EP3 can increase or be maximized.

In this way, the subpixel can have a three-dimensional (3D) structure (e.g., a flat center portion and inclined side portions) that allows for more light to be output in a direction toward a user while using a smaller footprint. In other words, according to an embodiment, smaller and brighter subpixels can be provided, which can save space, provide a wider viewing angle, increase resolution and reduce power consumption.

The light emitting display apparatus (or light emitting display panel) according to an embodiment of the present disclosure can further include a bank layer 170.

The bank layer 170 can be formed (or configured) to cover an edge portion of each of the plurality of first, second and third emission portions EP1, EP2, and EP3 in each of the plurality of subpixels SP. The bank layer 170 can be formed of an organic material such as benzocyclobutene (BCB)-based resin, acrylic-based resin, polyimide resin, or the like. For example, the bank layer 170 can be formed of a transparent material and can be a transparent bank. The bank layer 170 can be omitted, but is not limited thereto.

According to an embodiment of the present disclosure, the bank layer 170 can be formed (or configured) to cover an edge portion of the pixel electrode PE in each of the plurality of subpixels SP. The bank layer 170 can be formed (or configured) to cover the edge portion of each of the first, second and third pixel electrodes PE1, PE2, and PE3 in each of the plurality of subpixels SP. For example, in each of the plurality of subpixels SP, the bank layer 170 can be formed over the pattern portion 150 to cover the first slit SL1 between the first and second pixel electrodes PE1 and PE2 and can be formed over the pattern portion 150 to cover or overlap with the second slit SL2 between the first and third pixel electrodes PE1 and PE3. The bank layer 170 can be formed over the protection layer 130 between adjacent subpixels SP1 to SP4.

According to an embodiment of the present disclosure, the first emission portion EP1 can correspond to the other portion, except an edge portion, of the first pixel electrode PE1 covered by the bank layer 170 and can have a first width W1 along the first direction X. The second emission portion EP2 can correspond to the other portion, except an edge portion, of the second pixel electrode PE2 covered by the bank layer 170 and can have a second width W2 along the first direction X. The third emission portion EP3 can correspond to the other portion, except an edge portion, of the third pixel electrode PE3 covered by the bank layer 170 and can have a third width W3 along the first direction X. For example, the first width W1 of the first emission portion EP1 can be greater than the second width W2 of the second emission portion EP2 and the third width W3 of the third emission portion EP3. The second width W2 of the second emission portion EP2 and a third width W3 of the third emission portion EP3 can be equal to each other. The first width W1 of the first emission portion EP1 can be equal to a sum of the second width W2 of the second emission portion EP2 and the third width W3 of the third emission portion EP3, but is not limited thereto. For example, the first width W1 of the first emission portion EP1 can be greater or smaller than the sum of the second width W2 of the second emission portion EP2 and the third width W3 of the third emission portion EP3. For example, the bank layer 170 can be used to adjust the size of the emitting areas for the first emission portion EP1, the second emission portion EP2, and the third emission portion EP3 (e.g., by spacing the emitting layer EL apart from the pixel electrode PE).

According to an embodiment of the present disclosure, the light emitting display apparatus (or light emitting display panel) can further include a non-emission portion NEP. The light emitting display apparatus (or light emitting display panel) according to an embodiment of the present disclosure can further include a non-emission portion NEP corresponding to the bank layer 170 (e.g., the non-emission portion NEP can overlap with the bank layer 170). For example, the emission area EA of each of the plurality of pixels P can further include a plurality of non-emission portions NEP1, NEP2, and NEP3. For example, the emission area EA of each of the plurality of pixels P can further include a first non-emission portion NEP1 corresponding to the bank layer 170 between the first emission portion EP1 and the second emission portion EP2, a second non-emission portion NEP2 corresponding to the bank layer 170 between the first emission portion EP1 and the third emission portion EP3, and a third non-emission portion NEP3 corresponding to the bank layer 170 between the adjacent subpixels SP1 to SP4 (e.g., because the bank layer 170 can space the emitting layer EL apart from the pixel electrode PE).

According to an embodiment of the present disclosure, the emission layer EL of the light emitting device ED can be formed (or configured) over the pixel electrode PE and the bank layer 170. For example, the bank layer 170 can be formed between the emission layer EL and the pixel electrode PE or between the emission layer EL and the protective layer 130.

The light emitting display apparatus (or light emitting display panel) according to an embodiment of the present disclosure can further include a color filter layer 120.

The color filter layer 120 can be disposed between the substrate 100 and the protection layer 130 to overlap with at least one emission area EA. The color filter layer 120 according to an embodiment can be disposed between the passivation layer 119 and the protection layer 130 to overlap with the emission area EA. The color filter layer 120 according to another embodiment can be disposed between the substrate 100 and the interlayer insulating layer 115 or between the interlayer insulating layer 115 and the passivation layer 119 to overlap with the emission area EA.

The color filter layer 120 can have a larger size than the emission area EA. For example, when the color filter layer 120 has a greater size than the emission area EA, light leakage through which internal light travels toward the adjacent subpixels SP1 to SP4 can be reduced or minimized. For example, multiple color filters can be overlapped with each other in the areas between adjacent subpixels to form a black matrix. Also, the overlapping portions of color filters can be used to cover wiring lines (e.g., data lines DL) to help prevent reflections and color mixing.

The color filter layer 120 according to an embodiment can include a color filter which transmits only the wavelength of a color set in each subpixel SP1 to SP4 of the light emitted (or extracted) from the light emitting device ED toward the substrate 100. For example, the color filter layer 120 can transmit the red wavelength, green wavelength, or blue wavelength. For example, the color filter layer 120 provided at the first subpixel SP1 can include a red color filter 121, the color filter layer 120 provided at the third subpixel SP3 can include a blue color filter 122, and the color filter layer 120 provided at the fourth subpixel SP4 can include a green color filter. The third subpixel SP3 may not include a color filter layer 120 or can include a transparent material to compensate a step difference between adjacent pixels, thereby emitting white light.

According to another embodiment of the present disclosure, when each of the plurality of pixels P includes a red subpixel SP1, a blue subpixel SP2, and a green subpixel SP4, the color filter layer 120 can be omitted.

The light emitting display apparatus (or the light emitting display panel) according to an embodiment of the present disclosure can further include an encapsulation part 200.

The encapsulation part 200 can be formed over the substrate 100 to cover the light emitting device ED. The encapsulation part 200 can be formed over the common electrode CE of the light emitting device ED. For example, the encapsulation part 200 can surround the display area. The encapsulation part 200 can protect the thin film transistor and the emission layer EL or the like from external impact and prevent oxygen or/and water (or moisture) and particles from being permeated into the emission layer EL.

The encapsulation part 200 according to an embodiment of the present disclosure can include a plurality of inorganic encapsulation layer. In addition, the encapsulation part 200 can further include at least one organic encapsulation layer interposed between the plurality of inorganic encapsulation layer. The organic encapsulation layer can be expressed as a particle overlay layer.

The light emitting display apparatus (or the light emitting display panel) according to an embodiment of the present disclosure can further include a counter substrate 300. The counter substrate 300 can be configured to be coupled to the encapsulation part 200. The counter substrate 300 can be made of a plastic material, a glass material, or a metal material.

According to another embodiment of the present disclosure, the encapsulation part 200 can be changed to a filler that entirely surrounds (or completely surrounds) the display area DA, in this situation, the counter substrate 300 can be bonded to the substrate 100 using the filler. The filler can include a getter material that absorbs oxygen or/and water (or moisture). For example, when the encapsulation part 200 includes a plurality of inorganic encapsulation layers, the counter substrate 300 can be omitted.

The light emitting display apparatus (or the light emitting display panel) according to an embodiment of the present disclosure can further include a polarization member 400.

The polarization member 400 can be configured to block external light reflected by the pixel circuit PC or the like. For example, the polarization member 400 can be configured as a circular polarization member or a circular polarization film. The polarization member 400 can be disposed at or coupled to the light output surface (or a second surface or a rear surface) 100b of the substrate 100 using a coupling member (or a transparent adhesive member).

As described above, for the light emitting display apparatus according to an embodiment of the present disclosure, a viewing angle can be increased or widened based on different light output angles of lights L1, L2 and L3 emitted from the plurality of emission portions EP1, EP2, and EP3 or the plurality of sub emission portions EP2 and EP3 disposed in each of the plurality of subpixels SP1 to SP4. In addition, in the light emitting display apparatus according to an embodiment of the present disclosure, the light L1 emitted from the emission portion (or first emission portion) EP1 can be collected and output by the non-flat portion 153 formed at the pattern portion 150, and thus, light extraction efficiency corresponding to a front viewing angle can increase.

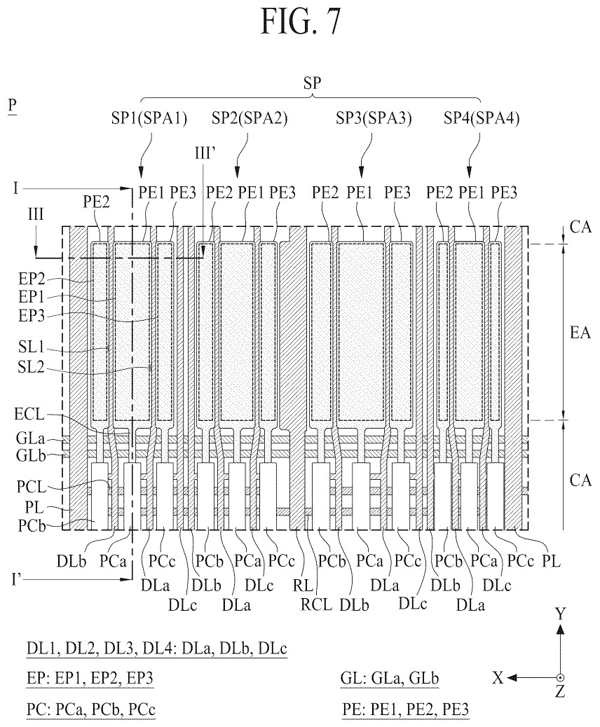

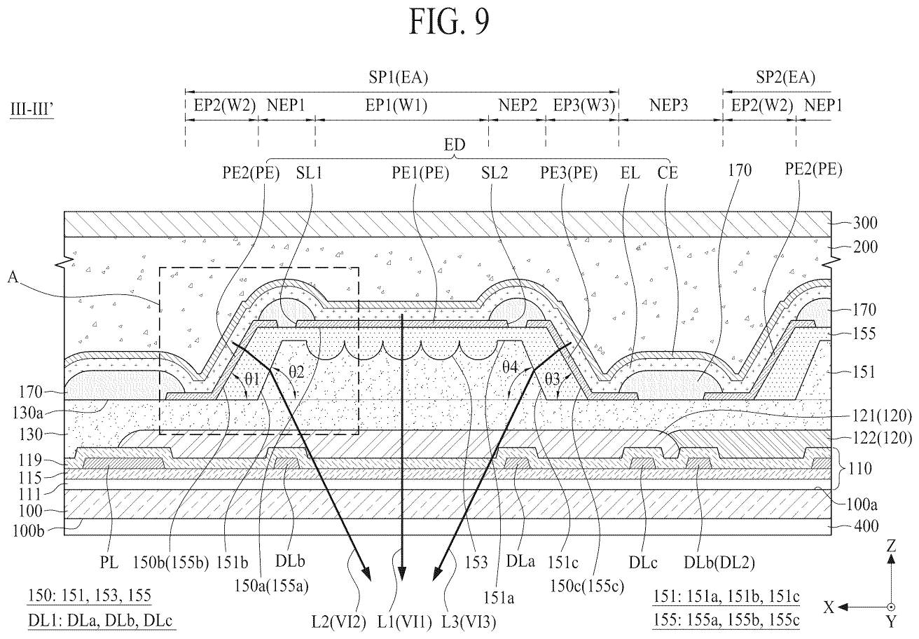

FIG. 7 is another plan view illustrating one pixel illustrated in FIG. 1 according to an embodiment of the present disclosure, FIG. 8 is an equivalent circuit view illustrating a first subpixel illustrated in FIG. 7 according to an embodiment of the present disclosure, and FIG. 9 is a cross-sectional view taken along line III-III′ illustrated in FIG. 7 according to an embodiment of the present disclosure. A cross-sectional view of line I-I′ illustrated in FIG. 7 is illustrated in FIG. 4, and an enlarged view of portion ‘A’ illustrated in FIG. 9 is illustrated in FIG. 6. FIGS. 7 to 9 illustrate an embodiment implemented by modifying a data line and a pixel circuit of each of a plurality of subpixels in the light emitting display apparatus (or a light emitting display panel) described above with reference to FIGS. 2 to 6. Therefore, in the following descriptions of FIGS. 7 to 9, the other elements except a data line and a pixel circuit and relevant elements are referred to by like reference numerals, and their repetitive descriptions can be omitted. Descriptions of the light emitting display apparatus (or light emitting display panel) illustrated in FIGS. 2 to 6 can be included in the descriptions of the light emitting display apparatus (or light emitting display panel) illustrated in FIGS. 7 to 9. For example, the light emitting display apparatus illustrated in FIGS. 7 to 9 is similar to the light emitting display apparatus illustrated in FIGS. 2 to 6, except that the different emission portions within each subpixel can be individually controlled, have its own corresponding circuit area, and a 3D mode and a 2D mode can be provided.

Referring to FIGS. 4 and 7 to 9, a light emitting display apparatus (or a light emitting display panel) according to another embodiment of the present disclosure can be configured to implement (or display) a stereoscopic image, and for example, implement a stereoscopic image through the light field mode. For example, the light emitting display apparatus according to another embodiment of the present disclosure can display a stereoscopic image through the individual light emission of each of a plurality of emission portions EP1, EP2, and EP3 configured at each of a plurality of subpixels SP, and for example, can implement (or display) a stereoscopic image based on the light field mode or can provide the stereoscopic image to a user (or a viewer).

In the light emitting display apparatus according to another embodiment of the present disclosure, each of a plurality of data lines DL1 to DL4 can include a plurality of sub data lines DLa, DLb, and DLc respectively corresponding to the plurality of emission portions EP1, EP2, and EP3 configured at each of the plurality of subpixels SP. For example, each of the plurality of data lines DL1 to DL4 respectively configured at the plurality of subpixels SP can include first to third sub data lines DLa, DLb, and DLc respectively corresponding to first to third emission portions EP1, EP2, and EP3. For example, a first data line DL1 configured at a first subpixel SP1 can include first to third sub data lines DLa, DLb, and DLc individually connected to the first to third emission portions EP1, EP2, and EP3. For example, each of the plurality of first to fourth data lines DL1 to DL4 can include a number of sub data lines DLa, DLb, and DLc equal to the number of emission portions EP1, EP2, and EP3 configured at one subpixel SP.

The plurality of first to third sub data lines DLa, DLb, and DLc can be disposed (or configured) to be electrically disconnected from one another in (within) one of subpixel areas SPA1 to SPA4.

According to an embodiment of the present disclosure, each of the first, second third sub data lines DLa, DLb, and DLc can be disposed to overlap with the bank layer 170 in each of the plurality of subpixels SP. For example, with respect to the thickness direction Z of the substrate 100, in the first and third subpixels SP1 and SP3 (or odd-numbered subpixels), the first sub data line DLa can be disposed to overlap with the bank layer 170 between the first pixel electrode PE1 and the third pixel electrode PE3, the second sub data line DLb can be disposed to overlap with the bank layer 170 between the first pixel electrode PE1 and the second pixel electrode PE2, and the third sub data line DLc can be disposed to overlap with the bank layer 170 covering an edge portion of the third pixel electrode PE3. For example, with respect to the thickness direction Z of the substrate 100, in the second and fourth subpixels SP2 and SP4 (or even-numbered subpixels), the first sub data line DLa can be disposed to overlap the bank layer 170 between the first pixel electrode PE1 and the second pixel electrode PE2, the second sub data line DLb can be disposed to overlap the bank layer 170 covering an edge portion of the second pixel electrode PE2, and the third sub data line DLc can be disposed to overlap the bank layer 170 between the first pixel electrode PE1 and the third pixel electrode PE3. For example, the third sub data line DLc in the first and third subpixels SP1 and SP3 can be disposed adjacent to the second sub data line DLb in the second and fourth subpixels SP2 and SP4.

According to an embodiment of the present disclosure, each of the plurality of subpixels SP can include three separate data lines. Accordingly, each of the plurality of subpixels SP can include a first data line corresponding to the first sub data line DLa, a second data line corresponding to the second sub data line DLb, and a third data line corresponding to a third sub data line DLc. For example, each of the plurality of subpixels SP can include a first sub data line (or first data line) DLa electrically connected to the first pixel circuit PCa, a second sub data line (or second data line) DLb electrically connected to the second pixel circuit PCb, and a third sub data line (or third data line) DLc electrically connected to the third pixel circuit PCc. Therefore, the light emitting display apparatus according to another embodiment of the present disclosure illustrated in FIGS. 7 to 9 can include data lines which are three times more than the number of data lines of the light emitting display apparatus according to an embodiment of the present disclosure illustrated in FIGS. 2 to 6.

In the light emitting display apparatus according to another embodiment of the present disclosure, a pixel circuit PC configured at each of the plurality of subpixels SP can be configured to be individually connected to the plurality of emission portions EP1, EP2, and EP3.

The pixel circuit PC according to another embodiment of the present disclosure can include a plurality of pixel circuits PCa, PCb, and PCc which are individually connected to a plurality of emission portions EP1, EP2, and EP3. For example, the pixel circuit PC can include first, second and third pixel circuits PCa, PCb, and PCc which are configured to be individually connected to first, second and third emission portions EP1, EP2, and EP3.

According to an embodiment of the present disclosure, the pixel circuit PC configured at each of the plurality of subpixels SP1 to SP4 can include a first pixel circuit PCa including a driving transistor (such as a driving TFT) Tdr electrically connected to the first pixel electrode PE1 of the first emission portion EP1, a second pixel circuit PCb including a driving transistor Tdr electrically connected to the second pixel electrode PE2 of the second emission portion EP2, and a third pixel circuit PCc including a driving transistor Tdr electrically connected to the third pixel electrode PE3 of the third emission portion EP3.

According to an embodiment of the present disclosure, each of the first, second and third pixel electrodes PE1, PE2, and PE3 can be spaced apart from (or electrically disconnected from) one another at the emission area EA and the circuit area CA and can be individually connected to the first, second and third pixel circuits PCa, PCb, and PCc in the circuit area CA. For example, one end of the first pixel electrode PE1 can extend into the circuit area CA and can be electrically connected to the driving transistor Tdr of the first pixel circuit PCa. One end of the second pixel electrode PE2 can extend into the circuit area CA and can be electrically connected to the driving transistor Tdr of the second pixel circuit PCb. One end of the third pixel electrode PE3 can extend into the circuit area CA and can be electrically connected to the driving transistor Tdr of the third pixel circuit PCc.

The first pixel circuit PCa can be connected to the gate line GL, the first sub data line DLa, the driving voltage line PL through the power connection line PCL, and the reference voltage line RL through the reference power connection line RCL. The first pixel circuit PCa can be configured to supply the first pixel electrode PE1 with a first field data current corresponding to a first field data voltage supplied through the first sub data line DLa in response to the gate signal supplied to a corresponding gate line GL. Accordingly, the first emission portion EP1 can emit light with the first field data current supplied from the first pixel circuit PCa to the first pixel electrode PE1.

The second pixel circuit PCb can be connected to the gate line GL, the second sub data line DLb, the driving voltage line PL through the power connection line PCL, and the reference voltage line RL through the reference power connection line RCL. The second pixel circuit PCb can be configured to supply the second pixel electrode PE2 with a second field data current corresponding to a second field data voltage supplied through the second sub data line DLb in response to the gate signal supplied to a corresponding gate line GL. Accordingly, the second emission portion EP2 can emit light with the second field data current supplied from the second pixel circuit PCb to the second pixel electrode PE2.

The third pixel circuit PCc can be connected to the gate line GL, the third sub data line DLc, the driving voltage line PL through the power connection line PCL, and the reference voltage line RL through the reference power connection line RCL. The third pixel circuit PCc can be configured to supply the third pixel electrode PE3 with a third field data current corresponding to a third field data voltage supplied through the third sub data line DLc in response to the gate signal supplied to a corresponding gate line GL. Accordingly, the third emission portion EP3 can emit light with the third field data current supplied from the third pixel circuit PCc to the third pixel electrode PE3.

According to an embodiment of the present disclosure, each of the first, second and third pixel circuits PCa, PCb, and PCc can include a first switching transistor Tsw1, a second switching transistor Tsw2, a driving transistor Tdr, and the storage capacitor Cst. Each of the first to third pixel circuits PCa, PCb, and PCc can be the same as or substantially the same as the pixel circuit PC described above with reference to FIGS. 3 and 4, and thus, the repetitive description thereof can be omitted.

Each of the plurality of gate lines GL can be connected to the first, second and third pixel circuits PCa, PCb, and PCc configured at each of the plurality of first to fourth subpixels SP1 to SP4 in common.

In each of the plurality of first to fourth data lines DL1 to DL4, the first sub data line DLa can be electrically connected to the first pixel circuit PCa and can supply the first pixel circuit PCa with the first field data voltage provided from the driving IC 35 described above with reference to FIG. 1. The second sub data line DLb can be electrically connected to the second pixel circuit PCb and can supply the second pixel circuit PCb with the second field data voltage provided from the driving IC 35. The third sub data line DLc can be electrically connected to the third pixel circuit PCc and can supply the third pixel circuit PCc with the third field data voltage provided from the driving IC 35.

According to an embodiment of the present disclosure, the first emission portion EP1 can selectively display a first viewing angle image VI1 corresponding to the first field data voltage, the second emission portion EP2 can selectively display a second viewing angle image VI2 corresponding to the second field data voltage, and the third emission portion EP3 can selectively display a third viewing angle image VI3 corresponding to the third field data voltage. For example, when the light emitting display apparatus is in the normal driving mode, the first, second and third viewing angle images VI1, VI2 and VI3 respectively displayed by the first, second and third emission portions EP1, EP2, and EP3 can be equal to one another, and in this situation, a viewing angle can increase or enlarge (e.g., a 2D mode with a wide viewing angle mode can be provided). For example, when the light emitting display apparatus is in the light field driving mode (or the stereoscopic image display mode, 3D mode), the first to third viewing angle images VI1 to VI3 respectively displayed by the first, second and third emission portions EP1, EP2, and EP3 can differ, and thus, a stereoscopic image of the light field mode can be implemented by each of the first to third viewing angle images VI1 to VI3. For example, the second emission portion EP2 can be a right-eye emission portion, and the third emission portion EP3 can be a left-eye emission portion. For example, the first viewing angle image VI1 can be a front image or a front viewing angle image. The second viewing angle image VI2 can be a first side image, a first side viewing angle image, or a right-eye image. The third viewing angle image VI3 can be a second side image, a second side viewing angle image, or a left-eye image. For example, one subpixel can have its first emission portion EP1 and its second emission portion EP2 activated while its third emission portion EP3 is deactivated for providing an image to the right eye of the user, and an adjacent subpixel can have its first emission portion EP1 and its third emission portion EP3 activated while its second emission portion EP2 is deactivated for providing an image to the left eye of the user, but embodiments are not limited thereto and various activation/deactivate combinations of the first, second and third emission portions EP1, EP2 and EP3 can be implemented for providing a 3D mode. For example, according to another embodiment, one subpixel can have its second emission portion EP2 activated while its first emission portion EP1 and third emission portion EP3 are both deactivated for providing an image to the right eye of the user, and an adjacent subpixel can have its third emission portion EP3 activated while its first emission portion EP1 and second emission portion EP2 are both deactivated for providing an image to the left eye of the user, etc.

In addition, according to another embodiment, a dual viewing mode (e.g., 2 person privacy mode or split screen mode) can be provided for two users that can watch different videos on the same display at the same time. For example, one subpixel can have its second emission portion EP2 activated while its first emission portion EP1 and third emission portion EP3 are both deactivated for providing an image to a first user sitting on a right side of the display device, and an adjacent subpixel can have its third emission portion EP3 activated while its first emission portion EP1 and second emission portion EP2 are both deactivated for providing a different image to a second user sitting on a left side of the display device, but embodiments are not limited thereto. For example, various activation/deactivate combinations of the first, second and third emission portions EP1, EP2 and EP3 for different subpixels can be implemented for providing a split screen 2D mode for displaying different images/videos to two different users at the same time.

The light emitting display apparatus according to another embodiment of the present disclosure described above with reference to FIGS. 7 to 9 can provide the same effect as that of the light emitting display apparatus according to an embodiment of the present disclosure described above with reference to FIGS. 2 to 6 and can implement (or display) a stereoscopic image (e.g., a stereoscopic image of the light field mode, 3D mode) by using an image displayed by each of a plurality of emission portions.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus comprising:
a plurality of pixels disposed on a substrate, each of the plurality of pixels including a plurality of subpixels,
wherein each of the plurality of subpixels includes:
a first emission portion;
a second emission portion adjacent to a first side of the first emission portion; and
a third emission portion adjacent to a second side of the first emission portion, and
wherein the second emission portion and the third emission portion are both inclined relative to the first emission portion.

2. The light emitting display apparatus of claim 1, wherein the second emission portion and the third emission portion are disposed parallel to each other with the first emission portion disposed therebetween, and
wherein an angle of light emitted from each of the second emission portion and the third emission portion differs from an angle of light emitted from the first emission portion.

3. The light emitting display apparatus of claim 1, wherein each of the plurality of subpixels further includes:
a pixel circuit connected to the first, second and third emission portions;
a protection layer covering the pixel circuit;
a pattern portion disposed over the protection layer; and
a light emitting device disposed over the pattern portion, and
wherein the first, second and third emission portions partially surround the pattern portion.

4. The light emitting display apparatus of claim 3, wherein the pattern portion includes:
an upper surface;
a first slope surface adjacent to a first side of the upper surface; and
a second slope surface adjacent to a second side of the upper surface,
wherein the first emission portion overlaps with a center of the upper surface of the pattern portion,
wherein the second emission portion overlaps with the first slope surface of the pattern portion, and
wherein the third emission portion overlaps with the second slope surface of the pattern portion.

5. The light emitting display apparatus of claim 4, wherein the light emitting device includes:
a first pixel electrode overlapping with the center of the upper surface of the pattern portion;
a second pixel electrode overlapping with the first slope surface of the pattern portion;
a third pixel electrode overlapping with the second slope surface of the pattern portion;
an emission layer disposed on the first, second and third pixel electrodes; and
a common electrode disposed on the emission layer.

6. The light emitting display apparatus of claim 5, further comprising:
a plurality of gate lines connected to the pixel circuit of each of the plurality of subpixels in common; and
a plurality of data lines disposed at the plurality of subpixels and at least one of the plurality of data lines being connected to the pixel circuit,
wherein the pixel circuit includes a driving transistor connected to the first, second and third pixel electrodes in common.

7. The light emitting display apparatus of claim 5, wherein the pixel circuit of each of the plurality of subpixels includes:
a first pixel circuit including a first driving transistor electrically connected to the first pixel electrode;
a second pixel circuit including a second driving transistor electrically connected to the second pixel electrode; and
a third pixel circuit including a third driving transistor electrically connected to the third pixel electrode.

8. The light emitting display apparatus of claim 7, further comprising a gate line connected to the first, second and third pixel circuits in common,
wherein each of the plurality of subpixels includes:
a first data line electrically connected to the first pixel circuit;
a second data line electrically connected to the second pixel circuit; and
a third data line electrically connected to the third pixel circuit.

9. The light emitting display apparatus of claim 4, wherein the upper surface of the pattern portion is a flat surface, or
wherein an angle between an upper surface of the protection layer and each of the first slope surface and the second slope surface of the pattern portion is an acute angle.

10. The light emitting display apparatus of claim 4, wherein the pattern portion includes:
a first pattern layer disposed on the protection layer; and
a second pattern layer at least partially surrounding the first pattern layer, and
wherein the second pattern layer includes the upper surface, the first slope surface, and the second slope surface.

11. The light emitting display apparatus of claim 10, wherein the first pattern layer and the second pattern layer have different refractive indexes, or
wherein a refractive index of the second pattern layer is higher than a refractive index of the first pattern layer.

12. The light emitting display apparatus of claim 10, wherein the first pattern layer includes:
a light extraction surface disposed under the upper surface of the second pattern layer, the light extraction surface including a plurality of concave portions;
a first lateral surface adjacent to a first side of the light extraction surface; and
a second lateral surface adjacent to a second side different from the first side of the light extraction surface.

13. The light emitting display apparatus of claim 12, wherein an angle between an upper surface of the protection layer and each of the first lateral surface and the second lateral surface is an acute angle, or
wherein an angle between the upper surface of the protection layer and each of the first slope surface and the second slope surface is smaller than or equal to the angle between the upper surface of the protection layer and each of the first lateral surface and the second lateral surface.

14. A display panel comprising:
a subpixel disposed on a substrate, the subpixel including:
a pattern portion disposed on the substrate;
a first emission portion disposed over a center of the pattern portion;
a second emission portion disposed on a first inclined surface of the pattern portion; and
a third emission portion disposed on a second inclined surface of the pattern portion.

15. The display panel of claim 14, wherein the pattern portion has a mesa shape or a trapezoid shape.

16. The display panel of claim 14, wherein the pattern portion includes a plurality of concave portions.

17. The display panel of claim 16, wherein the pattern portion includes a first pattern layer having a first refractive index and a second pattern layer having a second refractive index different than the first refractive index, and
wherein the plurality of concave portions are depressions in an upper surface of the first pattern layer.

18. The display panel of claim 14, wherein the first emission portion is spaced apart from the second emission portion by a first slit, and
wherein the first emission portion is spaced apart from the third emission portion by a second slit.

19. The display panel of claim 18, further comprising:
a first bank portion disposed on the first slit; and
a second bank portion disposed on the second slit.

20. The display panel of claim 14, further comprising:
an emission layer disposed continuously across the first, second and third emission portions.

21. The display panel of claim 14, wherein the first emission portion, the second emission portion and the third emission portion are connected to a first data line, a second data line and a third data line, respectively.

22. The display panel of claim 14, wherein the first emission portion, the second emission portion and the third emission portion are connected to a same data line.

23. The display panel of claim 14, wherein a slope of the second emission portion is equal to a slope of the third emission portion.

24. The display panel of claim 14, wherein the second emission portion and the third emission portion both have a same shape and are symmetrically disposed relative to the first emission portion.

25. The display panel of claim 14, wherein the first emission portion, the second emission portion and the third emission portion are configured to emit light of a same color.
